(19) United States
(12) Patent Application Publication
(10) Pub. No.: US 2025/0340478 A1
(43) Pub. Date: Nov. 6, 2025

(54) DIMENSIONALLY STABLE GLASSES

(71) Applicant: CORNING INCORPORATED, CORNING, NY (US)

(72) Inventors: Adam James Ellison, Corning, NY (US); Timothy James Kiczenski, Corning, NY (US); Ellen Anne King, Painted Post, NY (US); Adama Tandia, Corning, NY (US); Kochuparambil Deenamma Vargheese, Horseheads, NY (US)

(21) Appl. No.: 19/268,203

(22) Filed: Jul. 14, 2025

Related U.S. Application Data
(63) Continuation of application No. 17/277,904, filed on Mar. 19, 2021.
(60) Provisional application No. 62/736,070, filed on Sep. 25, 2018.

(51) Int. Cl. C03C 3/093; C03B 17/06; C03C 1/00; C03C 3/091

(52) U.S. Cl. CPC C03C 3/093; C03C 1/004; C03C 3/091; C03B 17/064

(57) ABSTRACT

Glasses that are substantially free of alkalis that possess high annealing points and, thus, good dimensional stability (i.e., low compaction) for use as TFT backplane substrates in amorphous silicon, oxide and low-temperature polysilicon TFT processes.

### CROSS-REFERENCE TO RELATED APPLICATION

This application is a continuation of U.S. patent application Ser. No. 17/277,904 filed on Mar. 19, 2021, which claims the benefit of national stage entry of International Patent Application Serial No. PCT/US2019/051010, filed on Sep. 13, 2019, which in turn, claims the benefit of priority under 35 U.S.C. § 119 of U.S. Provisional Application Ser. No. 62/736,070 filed on Sep. 25, 2018, the contents of each of which are relied upon and incorporated herein by reference in their entireties.

### TECHNICAL FIELD

Embodiments of the present disclosure utilize a surprising combination of a high liquidus viscosity and a viscosity curve which allows glasses meeting a certain threshold of customer facing attributes to be manufactured with better cost and quality relative to any previously disclosed glass compositions.

### BACKGROUND

The production of liquid crystal displays, for example, active matrix liquid crystal display devices (AMLCDs) is very complex, and the properties of the substrate glass are important. First and foremost, the glass substrates used in the production of AMLCD devices need to have their physical dimensions tightly controlled. The downdraw sheet drawing processes and, in particular, the fusion process described in U.S. Pat. Nos. 3,338,696 and 3,682,609, both to Dockerty, are capable of producing glass sheets that can be used as substrates without requiring costly post-forming finishing operations such as lapping and polishing. Unfortunately, the fusion process places rather severe restrictions on the glass properties, which require relatively high liquidus viscosities.

In the liquid crystal display field, thin film transistors (TFTs) based on poly-crystalline silicon are preferred because of their ability to transport electrons more effectively. Poly-crystalline based silicon transistors (p-Si) are characterized as having a higher mobility than those based on amorphous-silicon based transistors (a-Si). This allows the manufacture of smaller and faster transistors, which ultimately produces brighter and faster displays.

### SUMMARY OF THE CLAIMS

One or more embodiments of the present disclosure provide a glass substantially free of alkalis comprising, in mole percent on an oxide basis: SiO₂: 66-70.5, Al₂O₃: 11.2-13.3, B₂O₃: 2.5-6, MgO: 2.5-6.3, CaO 2.7-8.3, SrO 1-5.8, BaO 0-3, wherein SiO₂, Al₂O₃, B₂O₃, MgO, CaO, SrO and BaO represent the mole percents of the oxide components. Further embodiments include a RO/Al2O3 ratio of 0.98≤(MgO+CaO+SrO+BaO)/Al2O3≤1.38 or an Mg/RO ratio of 0.18≤MgO/(MgO+CaO+SrO+BaO)≤0.45. Some embodiments may also contain 0.01 to 0.4 mol % of any one or combination of SnO₂, As₂O₃, or Sb₂O₃, F, Cl or Br as a chemical fining agent. Some embodiments may also contain 0.005 to 0.2 mol % of any one of combination of Fe₂O₃, CeO₂, or MnO₂ as a chemical fining agent. Some embodiments may have an annealing point greater than 750° C., greater than 765° C., or greater than 770° C. Some embodiments may have a liquidus viscosity greater than 100,000 Poise, greater than 150,000 Poise, or greater than 180,000 Poise. Some embodiments may have a Young's Modulus of greater than 80 GPa, greater than 81 GPa, or greater than 81.5 GPa. Some embodiments may have a density less than 2.55 g/cc, less than 2.54 g/cc, or less than 2.53 g/cc. Some embodiments may have a T200P less than 1665° C., less than 1650° C., or less than 1640° C. Some embodiments may have a T35kP less than 1280° C., less than 1270° C., or less than 1266° C. Some embodiments may have a T200P−T(ann) less than 890° C., less than 880° C., less than 870° C., or less than 865° C. Some embodiments may have a T200P−T(ann) less than 890° C., T(ann)≥750° C., Young's Modulus of greater than 80 GPa, a density less than 2.55 g/cc, and a liquidus viscosity of greater than 100,000 Poise. Some embodiments may have a T200P−T(ann) less than 880° C., T(ann)≥765° C., Young's Modulus of greater than 81 GPa, a density less than 2.54 g/cc, and a liquidus viscosity of greater than 150,000 Poise. Some embodiments may have a T200P−T(ann) less than 865° C., T(ann)≥770° C., Young's Modulus of greater than 81.5 GPa, a density less than 2.54 g/cc, and a liquidus viscosity of greater than 180,000 Poise. In some embodiments, As₂O₃ and Sb₂O₃ comprise less than about 0.005 mol %. In some embodiments, Li₂O, Na₂O, K₂O, or combinations thereof, comprise less than about 0.1 mol % of the glass. In some embodiments, the raw materials comprise between 0 and 200 ppm sulfur by weight for each raw material employed. Exemplary objects comprising these glasses can be produced by a downdraw sheet fabrication process or a fusion process or a variant thereof.

Some embodiments provide a glass substantially free of alkalis comprising, in mole percent on an oxide basis: SiO₂: 68-79.5, Al₂O₃: 12.2-13, B₂O₃: 3.5-4.8, MgO: 3.7-5.3, CaO 4.7-7.3, SrO 1.5-4.4, BaO 0-2, where SiO₂, Al₂O₃, B₂O₃, MgO, CaO, SrO and BaO represent the mole percents of the oxide components. Further embodiments include a RO/Al2O3 ratio of 1.07≤(MgO+CaO+SrO+BaO)/Al2O3≤1.2 or an MgO/RO ratio of 0.24≤MgO/(MgO+CaO+SrO+BaO)≤0.36. Some embodiments may also contain 0.01 to 0.4 mol % of any one or combination of SnO₂, As₂O₃, or Sb₂O₃, F, Cl or Br as a chemical fining agent. Some embodiments may also contain 0.005 to 0.2 mol % of any one of combination of Fe₂O₃, CeO₂, or MnO₂ as a chemical fining agent. Some embodiments may have a T200P−T(ann) less than 890° C., T(ann)≥750° C., Young's Modulus of greater than 80 GPa, a density less than 2.55 g/cc, and a liquidus viscosity of greater than 100,000 Poise. Some embodiments may have a T200P−T(ann) less than 880° C., T(ann)≥765° C., Young's Modulus of greater than 81 GPa, a density less than 2.54 g/cc, and a liquidus viscosity of greater than 150,000 Poise. Some embodiments may have a T200P−T(ann) less than 865° C., T(ann)≥770° C., Young's Modulus of greater than 81.5 GPa, a density less than 2.54 g/cc, and a liquidus viscosity of greater than 180,000 Poise. In some embodiments, As₂O₃ and Sb₂O₃ comprise less than about 0.005 mol %. In some embodiments, Li₂O, Na₂O, K₂O, or combinations thereof, comprise less than about 0.1 mol % of the glass. In some embodiments, the raw materials comprise between 0 and 200 ppm sulfur by weight for each raw material employed. Exemplary objects comprising these glasses can be produced by a downdraw sheet fabrication process or a fusion process or a variant thereof.

Some embodiments provide a glass substantially free of alkalis comprising, in mole percent on an oxide basis: SiO₂: 68.3-69.5, Al₂O₃: 12.4-13, B₂O₃: 3.7-4.5, MgO: 4-4.9, CaO 5.2-6.8, SrO 2.5-4.2, BaO 0-1, where SiO₂, Al₂O₃, B₂O₃, MgO, CaO, SrO and BaO represent the mole percents of the oxide components. Further embodiments include a RO/Al2O3 ratio of 1.09≤(MgO+CaO+SrO+BaO)/Al₂O₃≤1.16 or an MgO/RO ratio of 0.25≤MgO/(MgO+CaO+SrO+BaO)≤0.35. Some embodiments may also contain 0.01 to 0.4 mol % of any one or combination of SnO₂, As₂O₃, or Sb₂O₃, F, Cl or Br as a chemical fining agent. Some embodiments may also contain 0.005 to 0.2 mol % of any one of combination of Fe₂O₃, CeO₂, or MnO₂ as a chemical fining agent. Some embodiments may have a T200P−T(ann) less than 890° C., T(ann)≥750° C., Young's Modulus of greater than 80 GPa, a density less than 2.55 g/cc, and a liquidus viscosity of greater than 100,000 Poise. Some embodiments may have a T200P−T(ann) less than 880° C., T(ann)≥765° C., Young's Modulus of greater than 81 GPa, a density less than 2.54 g/cc, and a liquidus viscosity of greater than 150,000 Poise. Some embodiments may have a T200P−T(ann) less than 865° C., T(ann)≥770° C., Young's Modulus of greater than 81.5 GPa, a density less than 2.54 g/cc, and a liquidus viscosity of greater than 180,000 Poise. In some embodiments, As₂O₃ and Sb₂O₃ comprise less than about 0.005 mol %. In some embodiments, Li₂O, Na₂O, K₂O, or combinations thereof, comprise less than about 0.1 mol % of the glass. In some embodiments, the raw materials comprise between 0 and 200 ppm sulfur by weight for each raw material employed. Exemplary objects comprising these glasses can be produced by a downdraw sheet fabrication process or a fusion process or a variant thereof.

Some embodiments provide a glass having a Young's modulus in the range defined by the relationship: 70 GPa≤549.899-4.811*SiO₂-4.023*Al₂O₃-5.651*B₂O₃-4.004*MgO-4.453*CaO-4.753*SrO-5.041*BaO≤90 GPa, where SiO2, Al2O3, B2O3, MgO, CaO, SrO and BaO represent the mole percents of the oxide components. Further embodiments include a RO/Al2O3 ratio of 1.07≤(MgO+CaO+SrO+BaO)/Al2O3≤1.2. Some embodiments may also contain 0.01 to 0.4 mol % of any one or combination of SnO₂, As₂O₃, or Sb₂O₃, F, Cl or Br as a chemical fining agent. Some embodiments may also contain 0.005 to 0.2 mol % of any one of combination of Fe₂O₃, CeO₂, or MnO₂ as a chemical fining agent. In some embodiments, As₂O₃ and Sb₂O₃ comprise less than about 0.005 mol %. In some embodiments, Li₂O, Na₂O, K₂O, or combinations thereof, comprise less than about 0.1 mol % of the glass. In some embodiments, the raw materials comprise between 0 and 200 ppm sulfur by weight for each raw material employed. Exemplary objects comprising these glasses can be produced by a downdraw sheet fabrication process or a fusion process or a variant thereof.

Some embodiments provide a glass having an Annealing Point in the range defined by the relationship: 720° C.≤1464.862-6.339*SiO₂-1.286*Al₂O₃-17.284*B₂O₃-12.216*MgO-11.448*CaO-11.367*SrO-12.832*BaO≤810° C., where SiO₂, Al₂O₃, B₂O₃, MgO, CaO, SrO and BaO represent the mole percents of the oxide components. Further embodiments include a RO/Al2O3 ratio of 1.07≤(MgO+CaO+SrO+BaO)/Al2O3≤1.2. Some embodiments may also contain 0.01 to 0.4 mol % of any one or combination of SnO₂, As₂O₃, or Sb₂O₃, F, Cl or Br as a chemical fining agent. Some embodiments may also contain 0.005 to 0.2 mol % of any one of combination of Fe₂O₃, CeO₂, or MnO₂ as a chemical fining agent. In some embodiments, As₂O₃ and Sb₂O₃ comprise less than about 0.005 mol %. In some embodiments, Li₂O, Na₂O, K₂O, or combinations thereof, comprise less than about 0.1 mol % of the glass. In some embodiments, the raw materials comprise between 0 and 200 ppm sulfur by weight for each raw material employed. Exemplary objects comprising these glasses can be produced by a downdraw sheet fabrication process or a fusion process or a variant thereof.

Additional embodiments of the disclosure are directed to an object comprising the glass produced by a downdraw sheet fabrication process. Further embodiments are directed to glass produced by the fusion process or variants thereof.

### BRIEF DESCRIPTION OF THE DRAWINGS

The accompanying figures, which are incorporated in and constitute a part of this specification, illustrate several embodiments described below.

FIG. 1 shows a schematic representation of a forming mandrel used to make precision sheet in the fusion draw process;

FIG. 2 shows a cross-sectional view of the forming mandrel of FIG. 1 taken along position 6;

FIG. 3 is a graph of a Convex Hull for some embodiments of the present disclosure;

FIG. 4 is a graph of a Convex Hull for other embodiments of the present disclosure;

FIG. 5 is a graph of a Convex Hull for additional embodiments of the present disclosure;

FIG. 6 is a graph of a Convex Hull for further embodiments of the present disclosure;

FIG. 7 is a graphical representation of Equation (1) for some embodiments randomly selected inside the Convex Hull of FIG. 3; and

FIG. 8 is a graphical representation of Equation (2) for some embodiments randomly selected inside the Convex Hull of FIG. 3.

### DETAILED DESCRIPTION

One problem with p-Si based transistors is that their manufacture requires higher process temperatures than those employed in the manufacture of a-Si transistors. These temperatures range from 450° C. to 600° C. compared to the 350° C. peak temperatures employed in the manufacture of a-Si transistors. At these temperatures, most AMLCD glass substrates undergo a process known as compaction. Compaction, also referred to as thermal stability or dimensional change, is an irreversible dimensional change (shrinkage) in the glass substrate due to changes in the glass' fictive temperature. “Fictive temperature” is a concept used to indicate the structural state of a glass. Glass that is cooled quickly from a high temperature is said to have a higher fictive temperature because of the “frozen in” higher temperature structure. Glass that is cooled more slowly, or that is annealed by holding for a time near its annealing point, is said to have a lower fictive temperature.

The magnitude of compaction depends both on the process by which a glass is made and the viscoelastic properties of the glass. In the float process for producing sheet products from glass, the glass sheet is cooled relatively slowly from the melt and, thus, “freezes in” a comparatively low temperature structure into the glass. The fusion process, by contrast, results in very rapid quenching of the glass sheet from the melt, and freezes in a comparatively high temperature structure. As a result, a glass produced by the float process may undergo less compaction when compared to glass produced by the fusion process, since the driving force for compaction is the difference between the fictive temperature and the process temperature experienced by the glass during compaction. Thus, it would be desirable to minimize the level of compaction in a glass substrate that is produced by a downdraw process.

There are two approaches to minimize compaction in glass. The first is to thermally pretreat the glass to create a fictive temperature similar to the one the glass will experience during the p-Si TFT manufacture. There are several difficulties with this approach. First, the multiple heating steps employed during the p-Si TFT manufacture create slightly different fictive temperatures in the glass that cannot be fully compensated for by this pretreatment. Second, the thermal stability of the glass becomes closely linked to the details of the p-Si TFT manufacture, which could mean different pretreatments for different end-users. Finally, pretreatment adds to processing costs and complexity.

Another approach is to slow the rate of strain at the process temperature by increasing the viscosity of the glass. This can be accomplished by raising the viscosity of the glass. The annealing point represents the temperature corresponding to a fixed viscosity for a glass, and thus an increase in annealing point equates to an increase in viscosity at fixed temperature. The challenge with this approach, however, is the production of high annealing point glass that is cost effective. The main factors impacting cost are defects and asset lifetime. In a conventional melter coupled to a fusion draw machine, four types of defects are commonly encountered: (1) gaseous inclusions (bubbles or blisters); (2) solid inclusions from refractories or from failure to properly melt the batch; (3) metallic defects consisting largely of platinum; and (4) devitrification products resulting from low liquidus viscosity or excessive devitrification at either end of the isopipe. Glass composition has a disproportionate impact on the rate of melting, and hence on the tendency of a glass to form gaseous or solid defects, and the oxidation state of the glass impacts the tendency to incorporate platinum defects. Devitrification of the glass on the forming mandrel, or isopipe, is best managed by selecting compositions with high liquidus viscosities.

Asset lifetime is determined mostly by the rate of wear or deformation of the various refractory and precious metal components of the melting and forming systems. Recent advances in refractory materials, platinum system design, and isopipe refractories have offered the potential to greatly extend the useful operational lifetime of a conventional melter coupled to a fusion draw machine. As a result, the lifetime-limiting component of a conventional fusion draw melting and forming platform is the electrodes used to heat the glass. Tin oxide electrodes corrode slowly over time, and the rate of corrosion is strong function both of temperature and glass composition. To maximize asset lifetime, it is desirable to identify compositions that reduce the rate of electrode corrosion while maintaining the defect-limiting attributes described above.

Described herein are alkali-free glasses and methods for making the same that possess high annealing points and, thus, good dimensional stability (i.e., low compaction). Additionally, exemplary compositions have very high liquidus viscosities, thus reducing or eliminating the likelihood of devitrification on the forming mandrel. As a result of specific details of their composition, exemplary glasses melt to good quality with very low levels of gaseous inclusions, and with minimal erosion to precious metals, refractories, and tin oxide electrode materials.

The embodiments described herein also maintain excellent Total Pitch Variation (TPV) while improving the manufacturability and cost relative to the existing Lotus glass families. This is accomplished through the unique combination of a viscosity curve with high liquidus viscosity while maintaining density and CTE in the traditionally desired ranges for display applications. Prior glasses with adequate annealing points may have demonstrated some of these attributes but not all simultaneously, making this a unique and surprising composition space.

Described herein are glasses that are substantially free of alkalis that possess high annealing points and, thus, good dimensional stability (i.e., low compaction) for use as TFT backplane substrates in amorphous silicon, oxide and low-temperature polysilicon TFT processes. Exemplary glasses described herein also find suitable use for high-performance displays with a-Si and oxide-TFT technologies. A high annealing point glass can prevent panel distortion due to compaction/shrinkage or stress relaxation during thermal processing subsequent to manufacturing of the glass. The disclosed glasses have the added feature of relatively low melting and fining temperature due to their viscosity curves. For glasses with such viscosity curves, exemplary glasses also possess unusually high liquidus viscosity, and thus a significantly reduced risk to devitrification at cold places in the forming apparatus. It is to be understood that while low alkali concentrations are generally desirable, in practice it may be difficult or impossible to economically manufacture glasses that are entirely free of alkalis. The alkalis in question arise as contaminants in raw materials, as minor components in refractories, etc., and can be very difficult to eliminate entirely. Therefore, exemplary glasses are considered substantially free of alkalis if the total concentration of the alkali elements Li₂O, Na₂O, and K₂O is less than about 0.1 mole percent (mol %).

In one embodiment, the substantially alkali-free glasses have annealing points greater than about 750° C., greater than 765° C., or greater than 770° C. To enable the use of exemplary glasses as backplane substrates or carriers, such high annealing points provide low rates of relaxation (via either compaction, stress relaxation, or both) and therefore small amounts of dimensional change. In another embodiment, at a viscosity of 35,000 Poise, exemplary glasses have a corresponding temperature (T35kP) of less than about 1280° C., less than 1270° C., or less than 1266° C. The liquidus temperature of a glass (Tliq) is the highest temperatures above which no crystalline phases can coexist in equilibrium with the glass. In another embodiment, the viscosity corresponding to the liquidus temperature of the glass is greater than about 100,000 Poise, greater than about 150,000 Poise, or greater than about 180,000 Poise. In another embodiment, at a viscosity of 200 Poise, exemplary glasses have a corresponding temperature (T200P) of less than about 1665° C., less than 1650° C., or less than 1640° C. In another embodiment, exemplary glasses have a difference in temperature between T200P and the annealing point (T(ann)) of less than 890° C., less than 880° C., less than 870° C., or less than 865° C.

In one embodiment the substantially alkali-free glass comprises in mole percent on an oxide basis: SiO₂: 66-70.5; Al₂O₃: 11.2-13.3; B₂O₃: 2.5-6; MgO: 2.5-6.3; CaO: 2.7-8.3; SrO: 1-5.8; BaO: 0-3, wherein 0.98≤(MgO+CaO+SrO+BaO)/Al₂O₃≤1.38, and 0.18≤MgO/(MgO+CaO+SrO+BaO)≤0.45, wherein Al₂O₃, MgO, CaO, SrO, BaO represent the mole percents of the respective oxide components.

In a further embodiment, the substantially alkali-free glass comprises in mole percent on an oxide basis: SiO₂: 68-69.5; Al₂O₃: 12.2-13; B₂O₃: 3.5-4.8; MgO: 3.7-5.3; CaO: 4.7-7.3; SrO: 1.5-4.4; BaO: 0-2, wherein 1.07≤(MgO+CaO+SrO+BaO)/Al₂O₃<1.2, and 0.24≤MgO/(MgO+CaO+SrO+BaO)≤0.36, wherein Al₂O₃, MgO, CaO, SrO, BaO represent the mole percents of the respective oxide components.

In a further embodiment, the substantially alkali-free glass comprises in mole percent on an oxide basis: SiO₂: 68.3-69.5; Al₂O₃: 12.4-13; B₂O₃: 3.7-4.5; MgO: 4-4.9; CaO: 5.2-6.8; SrO: 2.5-4.2; BaO: 0-1, wherein 1.09<(MgO+CaO+SrO+BaO)/Al₂O₃≤1.16, and 0.25≤MgO/(MgO+CaO+SrO+BaO)≤0.35, wherein Al₂O₃, MgO, CaO, SrO, BaO represent the mole percents of the respective oxide components.

In one embodiment, an exemplary glass includes a chemical fining agent. Such fining agents include, but are not limited to, SnO₂, As₂O₃, Sb₂O₃, F, Cl and Br, and in which the concentrations of the chemical fining agents are kept at a level of 0.5 mol % or less. Chemical fining agents may also include CeO₂, Fe₂O₃, and other oxides of transition metals, such as MnO₂. These oxides may introduce color to the glass via visible absorptions in their final valence state(s) in the glass, and thus their concentration can be kept at a level of 0.2 mol % or less.

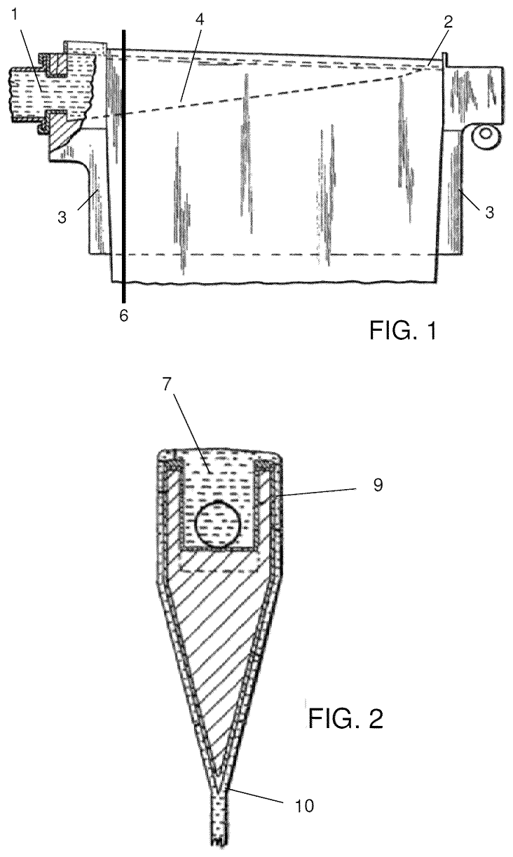

In one embodiment, exemplary glasses are manufactured into sheet via the fusion process. The fusion draw process results in a pristine, fire-polished glass surface that reduces surface-mediated distortion to high resolution TFT backplanes and color filters. FIG. 1 is a schematic drawing of the fusion draw process at the position of the forming mandrel, or isopipe, so called because its gradient trough design produces the same (hence “iso”) flow at all points along the length of the isopipe (from left to right). FIG. 2 is a schematic cross-section of the isopipe near position 6 in FIG. 1. Glass is introduced from the inlet 1, flows along the bottom of the trough 4 formed by the weir walls 9 to the compression end 2. Glass 7 overflows the weir walls 9 on either side of the isopipe (see FIG. 2), and the two streams of glass join or fuse at the root 10. Edge directors 3 at either end of the isopipe serve to cool the glass and create a thicker strip at the edge called a bead. The bead is pulled down by pulling rolls, hence enabling sheet formation at high viscosity. By adjusting the rate at which sheet is pulled off the isopipe, it is possible to use the fusion draw process to produce a very wide range of thicknesses at a fixed melting rate.

The downdraw sheet drawing processes and, in particular, the fusion process described in U.S. Pat. Nos. 3,338,696 and 3,682,609 (both to Dockerty), which are incorporated by reference, can be used herein. Compared to other forming processes, such as the float process, the fusion process is preferred for several reasons. First, glass substrates made from the fusion process do not require polishing. Current glass substrate polishing is capable of producing glass substrates having an average surface roughness greater than about 0.5 nm (Ra), as measured by atomic force microscopy. The glass substrates produced by the fusion process have an average surface roughness as measured by atomic force microscopy of less than 0.5 nm. The substrates also have an average internal stress as measured by optical retardation which is less than or equal to 150 psi.

In one embodiment, exemplary glasses are manufactured into sheet form using the fusion process. While exemplary glasses are compatible with the fusion process, they may also be manufactured into sheets or other ware through less demanding manufacturing processes. Such processes include slot draw, float, rolling, and other sheet-forming processes known to those skilled in the art. Thus, the claims appended herewith should not be so limited to fusion processes as embodiments described herein are equally applicable to other forming processes such as, but not limited to, float forming processes.

Relative to these alternative methods for creating sheets of glass, the fusion process as discussed above is capable of creating very thin, very flat, very uniform sheets with a pristine surface. Slot draw also can result in a pristine surface, but due to change in orifice shape over time, accumulation of volatile debris at the orifice-glass interface, and the challenge of creating an orifice to deliver truly flat glass, the dimensional uniformity and surface quality of slot-drawn glass are generally inferior to fusion-drawn glass. The float process is capable of delivering very large, uniform sheets, but the surface is substantially compromised by contact with the float bath on one side, and by exposure to condensation products from the float bath on the other side. This means that float glass must be polished for use in high performance display applications.

Unlike the float process, the fusion process results in rapid cooling of the glass from high temperature, and this results in a high fictive temperature Tf: the fictive temperature can be thought of as representing the discrepancy between the structural state of the glass and the state it would assume if fully relaxed at the temperature of interest. We consider now the consequences of reheating a glass with a glass transition temperature Tg to a process temperature Tp such that Tp<Tg≤Tf. Since Tp<Tf, the structural state of the glass is out of equilibrium at Tp, and the glass will spontaneously relax toward a structural state that is in equilibrium at Tp. The rate of this relaxation scales inversely with the effective viscosity of the glass at Tp, such that high viscosity results in a slow rate of relaxation, and a low viscosity results in a fast rate of relaxation. The effective viscosity varies inversely with the fictive temperature of the glass, such that a low fictive temperature results in a high viscosity, and a high fictive temperature results in a comparatively low viscosity. Therefore, the rate of relaxation at Tp scales directly with the fictive temperature of the glass. A process that introduces a high fictive temperature results in a comparatively high rate of relaxation when the glass is reheated at Tp.

One means to reduce the rate of relaxation at Tp is to increase the viscosity of the glass at that temperature. The annealing point of a glass represents the temperature at which the glass has a viscosity of 10^{13.2} poise. As temperature decreases below the annealing point, the viscosity of the supercooled melt increases. At a fixed temperature below Tg, a glass with a higher annealing point has a higher viscosity than a glass with a lower annealing point. Therefore, to increase the viscosity of a substrate glass at Tp, one might choose to increase its annealing point. Unfortunately, it is generally the case that the composition changes necessary to increase the annealing point also increase viscosity at all other temperatures. In particular, the fictive temperature of a glass made by the fusion process corresponds to a viscosity of about 10¹¹-10¹² poise, so an increase in annealing point for a fusion-compatible glass generally increases its fictive temperature as well. For a given glass, higher fictive temperature results in lower viscosity at temperatures below Tg, and thus increasing fictive temperature works against the viscosity increase that would otherwise be obtained by increasing the annealing point. To see a substantial change in the rate of relaxation at Tp, it is generally necessary to make relatively large changes in the annealing point. An embodiment of an exemplary glass is that it has an annealing point greater than about 750° C., greater than 765° C., or greater than 770° C. Such high annealing points results in acceptably low rates of thermal relaxation during low-temperature TFT processing, e.g., typical low-temperature polysilicon rapid thermal anneal cycles or comparable cycles for oxide TFT processing.

In addition to its impact on fictive temperature, increasing annealing point also increases temperatures throughout the melting and forming system, particularly the temperatures on the isopipe. For example, Eagle XG® and Lotus™ (Corning Incorporated, Corning, NY) have annealing points that differ by about 50° C., and the temperature at which they are delivered to the isopipe also differ by about 50° C. When held for extended periods of time at high temperatures, zircon refractory shows thermal creep, and this can be accelerated by the weight of the isopipe itself plus the weight of the glass on the isopipe. A second embodiment of exemplary glasses is that their delivery temperatures are less than 1280° C. while simultaneously having annealing points above 750° C. Such delivery temperatures permit extended manufacturing campaigns without replacing the isopipe and the high annealing points allow the glasses to be used in the manufacture of high performance displays, such as those utilizing oxide TFT or LTPS processes.

In addition to this criterion, the fusion process typically involves a glass with a high liquidus viscosity. This is necessary so as to avoid devitrification products at interfaces with glass and to minimize visible devitrification products in the final glass. For a given glass compatible with fusion for a particular sheet size and thickness, adjusting the process so as to manufacture wider sheet or thicker sheet generally results in lower temperatures temperatures at either end of the isopipe (the forming mandrel for the fusion process). Thus, exemplary glasses with higher liquidus viscosities can provide greater flexibility for manufacturing via the fusion process.

To be formed by the fusion process, it is desirable that exemplary glass compositions have a liquidus viscosity greater than or equal to 130,000 poises, greater than or equal to 150,000 poises, or greater than or equal to 200,000 poises. A surprising result is that throughout the range of exemplary glasses, it is possible to obtain a liquidus temperature low enough, and a viscosity high enough, such that the liquidus viscosity of the glass is unusually high compared to compositions outside of an exemplary range.

In the glass compositions described herein, SiO₂ serves as the basic glass former. In certain embodiments, the concentration of SiO₂ can be 66 mole percent or greater in order to provide the glass with a density and chemical durability suitable for a flat panel display glass (e.g., an AMLCD glass), and a liquidus temperature (liquidus viscosity), which allows the glass to be formed by a downdraw process (e.g., a fusion process). In terms of an upper limit, in general, the SiO₂ concentration can be less than or equal to about 70.5 mole percent to allow batch materials to be melted using conventional, high volume, melting techniques, e.g., Joule melting in a refractory melter. As the concentration of SiO₂ increases, the 200 poise temperature (melting temperature) generally rises. In various applications, the SiO₂ concentration is adjusted so that the glass composition has a melting temperature less than or equal to 1665° C. In one embodiment, the SiO₂ concentration is between 66 and 70.5 mole percent.

Al₂O₃ is another glass former used to make the glasses described herein. An Al₂O₃ concentration greater than or equal to 11.2 mole percent provides the glass with a low liquidus temperature and high viscosity, resulting in a high liquidus viscosity. The use of at least 12 mole percent Al₂O₃ also improves the glass's annealing point and modulus. In order that the ratio (MgO+CaO+SrO+BaO)/Al₂O₃ is greater than or equal to 0.98, it is desirable to keep the Al₂O₃ concentration below about 13.3 mole percent. In one embodiment, the Al₂O₃ concentration is between 11.2 and 13.3 mole percent and in other embodiments, this range is kept while maintaining a ratio of (MgO+CaO+SrO+BaO)/Al₂O₃ greater than or equal to about 0.98.

B₂O₃ is both a glass former and a flux that aids melting and lowers the melting temperature. Its impact on liquidus temperature is at least as great as its impact on viscosity, so increasing B₂O₃ can be used to increase the liquidus viscosity of a glass. To maximize the liquidus viscosity of these glasses, the glass compositions described herein have B₂O₃ concentrations that are equal to or greater than 2.5 mole percent. As discussed above with regard to SiO₂, glass durability is very important for LCD applications. Durability can be controlled somewhat by elevated concentrations of alkaline earth oxides, and significantly reduced by elevated B₂O₃ content. Annealing point decreases as B₂O₃ increases, as does the Young's Modulus so it is desirable to keep B₂O₃ content low relative to its typical concentration in amorphous silicon substrates. Thus in one embodiment, the glasses described herein have B₂O₃ concentrations that are between 2.5 and 6 mole percent.

The Al₂O₃ and B₂O₃ concentrations can be selected as a pair to increase annealing point, increase modulus, improve durability, reduce density, and reduce the coefficient of thermal expansion (CTE), while maintaining the melting and forming properties of the glass.

For example, an increase in B₂O₃ and a corresponding decrease in Al₂O₃ can be helpful in obtaining a lower density and CTE, while an increase in Al₂O₃ and a corresponding decrease in B₂O₃ can be helpful in increasing annealing point, modulus, and durability, provided that the increase in Al₂O₃ does not reduce the (MgO+CaO+SrO+BaO)/Al₂O₃ ratio below about 1.0. For (MgO+CaO+SrO+BaO)/Al₂O₃ ratios below about 1.0, it may be difficult or impossible to remove gaseous inclusions from the glass due to late-stage melting of the silica raw material. Furthermore, when (MgO+CaO+SrO+BaO)/Al₂O₃≤1.05, mullite, an aluminosilicate crystal, can appear as a liquidus phase. Once mullite is present as a liquidus phase, the composition sensitivity of liquidus increases considerably, and mullite devitrification products both grow very quickly and are very difficult to remove once established. Thus in one embodiment, the glasses described herein have (MgO+CaO+SrO+BaO)/Al₂O₃≥1.05. Also, additional exemplary glasses for use in AMLCD applications have coefficients of thermal expansion (CTEs) (22-300° C.) in the range of 28-42×10-7/° C., 30-40×10-7/° C., or 32-38×10-7/° C.

In addition to the glass formers (SiO₂, Al₂O₃, and B₂O₃), the glasses described herein also include alkaline earth oxides. In one embodiment, at least three alkaline earth oxides are part of the glass composition, e.g., MgO, CaO, and BaO, and, optionally, SrO. In another embodiment, SrO is substituted for BaO. In another embodiment, all four of MgO, CaO, SrO, and BaO are present. The alkaline earth oxides provide the glass with various properties important to melting, fining, forming, and ultimate use. Accordingly, to improve glass performance in these regards, in one embodiment, the (MgO+CaO+SrO+BaO)/Al₂O₃ ratio is greater than or equal to 1.05. As this ratio increases, viscosity tends to decrease more strongly than liquidus temperature, and thus it is increasingly difficult to obtain suitably high values for liquidus viscosity. Thus in another embodiment, ratio (MgO+CaO+SrO+BaO)/Al₂O₃ is less than or equal to 1.38.

For certain embodiments, the alkaline earth oxides may be treated as what is in effect a single compositional component. This is because their impact upon viscoelastic properties, liquidus temperatures and liquidus phase relationships are qualitatively more similar to one another than they are to the glass forming oxides SiO₂, Al₂O₃ and B₂O₃. However, the alkaline earth oxides CaO, SrO and BaO can form feldspar minerals, notably anorthite (CaAl₂Si₂O₈) and celsian (BaAl₂Si₂O₈) and strontium-bearing solid solutions of same, but MgO does not participate in these crystals to a significant degree. Therefore, when a feldspar crystal is already the liquidus phase, a superaddition of MgO may serves to stabilize the liquid relative to the crystal and thus lower the liquidus temperature. At the same time, the viscosity curve typically becomes steeper, reducing melting temperatures while having little or no impact on low-temperature viscosities. In this sense, the addition of small amounts of MgO benefits melting by reducing melting temperatures, benefits forming by reducing liquidus temperatures and increasing liquidus viscosity, while preserving high annealing point and, thus, low compaction. Thus, in various embodiments, the glass composition comprises MgO in an amount in the range of about 2.5 mole percent to about 6.3 mole percent.

A surprising result of the investigation of liquidus trends in glasses with high annealing points is that for glasses with suitably high liquidus viscosities, the ratio of MgO to the other alkaline earths, MgO/(MgO+CaO+SrO+BaO), falls within a relatively narrow range. As noted above, additions of MgO can destabilize feldspar minerals, and thus stabilize the liquid and lower liquidus temperature. However, once MgO reaches a certain level, mullite, Al₆Si₂O1₃, may be stabilized, thus increasing the liquidus temperature and reducing the liquidus viscosity. Moreover, higher concentrations of MgO tend to decrease the viscosity of the liquid, and thus even if the liquidus viscosity remains unchanged by addition of MgO, it will eventually be the case that the liquidus viscosity will decrease. Thus in another embodiment, 0.18≤MgO/(MgO+CaO+SrO+BaO)≤0.45. Within this range, MgO may be varied relative to the glass formers and the other alkaline earth oxides to maximize the value of liquidus viscosity consistent with obtaining other desired properties.

Calcium oxide present in the glass composition can produce low liquidus temperatures (high liquidus viscosities), high annealing points and moduli, and CTE's in the most desired ranges for flat panel applications, specifically, AMLCD applications. It also contributes favorably to chemical durability, and compared to other alkaline earth oxides, it is relatively inexpensive as a batch material. However, at high concentrations, CaO increases the density and CTE. Furthermore, at sufficiently low SiO₂ concentrations, CaO may stabilize anorthite, thus decreasing liquidus viscosity. Accordingly, in one embodiment, the CaO concentration can be greater than or equal to 4 mole percent. In another embodiment, the CaO concentration of the glass composition is between about 2.7 and 8.3 mole percent.

SrO and BaO can both contribute to low liquidus temperatures (high liquidus viscosities) and, thus, the glasses described herein will typically contain at least both of these oxides. However, the selection and concentration of these oxides are selected in order to avoid an increase in CTE and density and a decrease in modulus and annealing point. The relative proportions of SrO and BaO can be balanced so as to obtain a suitable combination of physical properties and liquidus viscosity such that the glass can be formed by a downdraw process, with their combined concentration between 1 and 9 mol %. In some embodiments, the glass comprises SrO in range of about 1 mole percent to about 5.8 mole percent. In one or more embodiments, the glass comprises BaO in the range of about 0 to about 3 mole percent.

To summarize the effects/roles of the central components of the glasses of the disclosure, SiO₂ is the basic glass former. Al₂O₃ and B₂O₃ are also glass formers and can be selected as a pair with, for example, an increase in B₂O₃ and a corresponding decrease in Al₂O₃ being used to obtain a lower density and CTE, while an increase in Al₂O₃ and a corresponding decrease in B₂O₃ being used in increasing annealing point, modulus, and durability, provided that the increase in Al₂O₃ does not reduce the RO/Al₂O₃ ratio below about 1, where RO=(MgO+CaO+SrO+BaO). If the ratio goes too low, meltability may be compromised, i.e., the melting temperature may become too high. B₂O₃ can be used to bring the melting temperature down, but high levels of B₂O₃ compromise annealing point.

In addition to meltability and annealing point considerations, for AMLCD applications, the CTE of the glass should be compatible with that of silicon. To achieve such CTE values, exemplary glasses control the RO content of the glass. For a given Al₂O₃ content, controlling the RO content corresponds to controlling the RO/Al₂O₃ ratio. In practice, glasses having suitable CTE's are produced if the RO/Al₂O₃ ratio is below about 1.38.

On top of these considerations, the glasses can be formable by a downdraw process, e.g., a fusion process, which means that the glass' liquidus viscosity needs to be relatively high. Individual alkaline earths play an important role in this regard since they can destabilize the crystalline phases that would otherwise form. BaO and SrO are particularly effective in controlling the liquidus viscosity and are included in exemplary glasses for at least this purpose. As illustrated in the examples presented below, various combinations of the alkaline earths will produce glasses having high liquidus viscosities, with the total of the alkaline earths satisfying the RO/Al₂O₃ ratio constraints needed to achieve low melting temperatures, high annealing points, and suitable CTE's.

In addition to the above components, the glass compositions described herein can include various other oxides to adjust various physical, melting, fining, and forming attributes of the glasses. Examples of such other oxides include, but are not limited to, TiO₂, MnO, Fe₂O₃, ZnO, Nb₂O₅, MoO₃, ZrO₂, Ta₂O₅, WO₃, Y₂O₃, La₂O₃ and CeO₂. In one embodiment, the amount of each of these oxides can be less than or equal to 2.0 mole percent, and their total combined concentration can be less than or equal to 4.0 mole percent. The glass compositions described herein can also include various contaminants associated with batch materials and/or introduced into the glass by the melting, fining, and/or forming equipment used to produce the glass, particularly Fe₂O₃ and ZrO₂. The glasses can also contain SnO₂ either as a result of Joule melting using tin-oxide electrodes and/or through the batching of tin containing materials, e.g., SnO₂, SnO, SnCO₃, SnC₂O₂, etc.

The glass compositions are generally alkali free; however, the glasses can contain some alkali contaminants. In the case of AMLCD applications, it is desirable to keep the alkali levels below 0.1 mole percent to avoid having a negative impact on thin film transistor (TFT) performance through diffusion of alkali ions from the glass into the silicon of the TFT. As used herein, an “alkali-free glass” is a glass having a total alkali concentration which is less than or equal to 0.1 mole percent, where the total alkali concentration is the sum of the Na₂O, K₂O, and Li₂O concentrations. In one embodiment, the total alkali concentration is less than or equal to 0.1 mole percent.

As discussed above, (MgO+CaO+SrO+BaO)/Al₂O₃ ratios greater than or equal to 1 improve fining, i.e., the removal of gaseous inclusions from the melted batch materials. This improvement allows for the use of more environmentally friendly fining packages. For example, on an oxide basis, the glass compositions described herein can have one or more or all of the following compositional characteristics: (i) an As₂O₃ concentration of at most 0.05 mole percent; (ii) an Sb₂O₃ concentration of at most 0.05 mole percent; (iii) a SnO₂ concentration of at most 0.25 mole percent.

As₂O₃ is an effective high temperature fining agent for AMLCD glasses, and in some embodiments described herein, As₂O₃ is used for fining because of its superior fining properties. However, As₂O₃ is poisonous and requires special handling during the glass manufacturing process. Accordingly, in certain embodiments, fining is performed without the use of substantial amounts of As₂O₃, i.e., the finished glass has at most 0.05 mole percent As₂O₃. In one embodiment, no As₂O₃ is purposely used in the fining of the glass. In such cases, the finished glass will typically have at most 0.005 mole percent As₂O₃ as a result of contaminants present in the batch materials and/or the equipment used to melt the batch materials.

Although not as toxic as As₂O₃, Sb₂O₃ is also poisonous and requires special handling. In addition, Sb₂O₃ raises the density, raises the CTE, and lowers the annealing point in comparison to glasses that use As₂O₃ or SnO₂ as a fining agent. Accordingly, in certain embodiments, fining is performed without the use of substantial amounts of Sb₂O₃, i.e., the finished glass has at most 0.05 mole percent Sb₂O₃. In another embodiment, no Sb₂O₃ is purposely used in the fining of the glass. In such cases, the finished glass will typically have at most 0.005 mole percent Sb₂O₃ as a result of contaminants present in the batch materials and/or the equipment used to melt the batch materials.

Compared to As₂O₃ and Sb₂O₃ fining, tin fining (i.e., SnO₂ fining) is generally less effective, but SnO₂ is a ubiquitous material that has no known hazardous properties. Also, for many years, SnO₂ has been a component of AMLCD glasses through the use of tin oxide electrodes in the Joule melting of the batch materials for such glasses. The presence of SnO₂ in AMLCD glasses has not resulted in any known adverse effects in the use of these glasses in the manufacture of liquid crystal displays. However, high concentrations of SnO₂ are not preferred as this can result in the formation of crystalline defects in AMLCD glasses. In one embodiment, the concentration of SnO₂ in the finished glass is less than or equal to 0.25 mole percent.

Tin fining can be used alone or in combination with other fining techniques if desired. For example, tin fining can be combined with halide fining, e.g., bromine fining. Other possible combinations include, but are not limited to, tin fining plus sulfate, sulfide, cerium oxide, mechanical bubbling, and/or vacuum fining. It is contemplated that these other fining techniques can be used alone. In certain embodiments, maintaining the (MgO+CaO+SrO+BaO)/Al₂O₃ ratio and individual alkaline earth concentrations within the ranges discussed above makes the fining process easier to perform and more effective.

The glasses described herein can be manufactured using various techniques known in the art. In one embodiment, the glasses are made using a downdraw process such as, for example, a fusion downdraw process. In one embodiment, described herein is a method for producing an alkali-free glass sheet by a downdraw process comprising selecting, melting, and fining batch materials so that the glass making up the sheets comprises SiO₂, Al₂O₃, B₂O₃, MgO, CaO and BaO, and, on an oxide basis, comprises: (i) a (MgO+CaO+SrO+BaO)/Al₂O₃ ratio greater than or equal to 1; (ii) a MgO content greater than or equal to 2.5 mole percent; (iii) a CaO content greater than or equal to 2.7 mole percent; and (iv) a (SrO+BaO) content greater than or equal to 1 mole percent, wherein: (a) the fining is performed without the use of substantial amounts of arsenic (and, optionally, without the use of substantial amounts of antimony); and (b) a population of 50 sequential glass sheets produced by the downdraw process from the melted and fined batch materials has an average gaseous inclusion level of less than 0.10 gaseous inclusions/cubic centimeter, where each sheet in the population has a volume of at least 500 cubic centimeters.

U.S. Pat. No. 5,785,726 (Dorfeld et al.), U.S. Pat. No. 6,128,924 (Bange et al.), U.S. Pat. No. 5,824,127 (Bange et al.), and co-pending patent application Ser. No. 11/116,669 disclose processes for manufacturing arsenic free glasses. U.S. Pat. No. 7,696,113 (Ellison) discloses a process for manufacturing arsenic- and antimony-free glass using iron and tin to minimize gaseous inclusions. The entirety of each of U.S. Pat. Nos. 5,785,726, 6,128,924, 5,824,127, co-pending patent application Ser. No. 11/116,669, and U.S. Pat. No. 7,696,113 are incorporated herein by reference.

In one embodiment, the population of 50 sequential glass sheets produced by the downdraw process from the melted and fined batch materials has an average gaseous inclusion level of less than 0.05 gaseous inclusions/cubic centimeter, where each sheet in the population has a volume of at least 500 cubic centimeters.

In some embodiments, exemplary glasses having a high liquidus viscosity and a viscosity curve which meets a certain threshold of customer facing attributes and comprise the constituent ranges in Table 1 below, wherein Al₂O₃, MgO, CaO, SrO, BaO represent the mole percents of the respective oxide components.

TABLE 1

| Oxides | SiO2 | Al2O3 | B2O3 | MgO | CaO | SrO | BaO | SnO2 |
|---|---|---|---|---|---|---|---|---|
| Min | 65.93 | 11.04 | 2.83 | 2.75 | 3.98 | 1.97 | 0.00 | 0.08 |
| Max | 70.96 | 13.92 | 6.38 | 6.02 | 7.34 | 5.06 | 1.54 | 0.12 |

In some embodiments, exemplary glasses having a high liquidus viscosity and a viscosity curve which meets a certain threshold of customer facing attributes and comprise the constituent ranges in Table 2 below, wherein Al₂O₃, MgO, CaO, SrO, BaO represent the mole percents of the respective oxide components.

TABLE 2

| Oxides | SiO2 | Al2O3 | B2O3 | MgO | CaO | SrO | BaO | SnO2 |
|---|---|---|---|---|---|---|---|---|
| Min | 66.91 | 12.04 | 3.83 | 3.75 | 4.98 | 2.97 | 0.00 | 0.07 |
| Max | 70.46 | 13.42 | 5.88 | 5.52 | 6.84 | 4.56 | 1.04 | 0.12 |

In some embodiments, exemplary glasses having a high liquidus viscosity and a viscosity curve which meets a certain threshold of customer facing attributes and comprise the constituent ranges in Table 3 below, wherein Al₂O₃, MgO, CaO, SrO, BaO represent the mole percents of the respective oxide components.

TABLE 3

| Oxides | SiO2 | Al2O3 | B2O3 | MgO | CaO | SrO | BaO | SnO2 |
|---|---|---|---|---|---|---|---|---|
| Min | 68.22 | 12.41 | 3.83 | 4.11 | 5.34 | 3.33 | 0.00 | 0.08 |
| Max | 69.52 | 12.88 | 4.65 | 4.86 | 6.26 | 4.34 | 0.97 | 0.12 |

In some embodiments, exemplary glasses having a high liquidus viscosity and a viscosity curve which meets a certain threshold of customer facing attributes and comprise the constituent ranges in Table 4 below, wherein Al₂O₃, MgO, CaO, SrO, BaO represent the mole percents of the respective oxide components.

TABLE 4

| Oxides | SiO2 | Al2O3 | B2O3 | MgO | CaO | SrO | BaO | SnO2 |
|---|---|---|---|---|---|---|---|---|
| Min | 68.38 | 12.49 | 3.95 | 4.29 | 5.49 | 3.38 | 0.00 | 0.09 |
| Max | 69.52 | 12.71 | 4.42 | 4.61 | 5.62 | 4.12 | 0.75 | 0.11 |

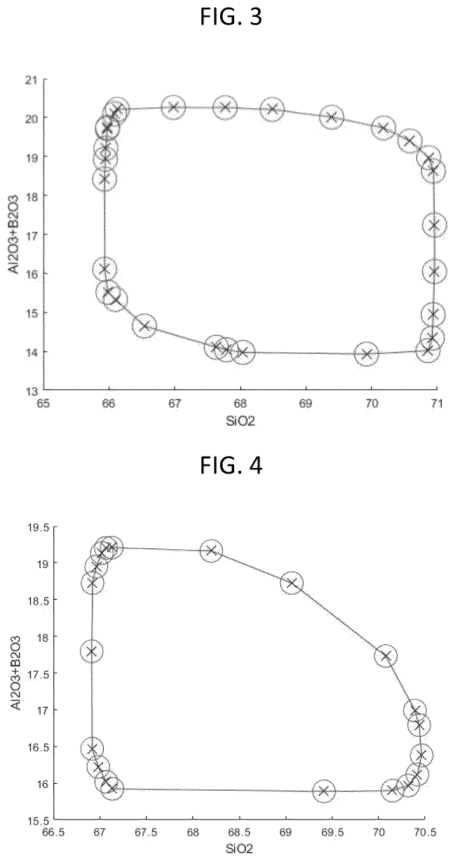

In some embodiments, some exemplary glass embodiments can be described by a Convex Hull, which corresponds to the smallest convex boundary that contains a set of points in a space of a given dimension. If one considers the space made up by any of the compositions contained in Tables 1, 2, 3, and 4, one can consider SiO₂ as a group, consider Al₂O₃ and B₂O₃ into a group named Al2O3_B2O3, and consider the remaining constituents into a group named RO, which contains MgO, CaO, SrO, BaO, SnO₂, and the other oxides listed in their respective ranges and define respective Convex Hulls for these compositions. For example, a ternary space can be defined by the space having a boundary set by the compositions of Table 1 in mole percent and as shown in FIG. 3. Table 5 below provides compositions (in mole percent) that define the boundary of the Convex Hull for the compositional range defined by Table 1.

TABLE 5

| SiO2 | Al2O3_B2O3 | RO |
|---|---|---|
| 65.98 | 19.71 | 14.31 |
| 65.95 | 19.21 | 14.84 |
| 65.95 | 18.93 | 15.13 |
| 65.93 | 18.42 | 15.65 |
| 65.93 | 16.10 | 17.96 |
| 65.99 | 15.51 | 18.50 |
| 66.10 | 15.33 | 18.57 |
| 66.54 | 14.65 | 18.81 |
| 67.64 | 14.10 | 18.26 |
| 67.79 | 14.04 | 18.17 |
| 68.04 | 13.97 | 17.99 |
| 69.92 | 13.93 | 16.15 |
| 70.86 | 14.01 | 15.13 |
| 70.92 | 14.33 | 14.74 |
| 70.94 | 14.94 | 14.12 |
| 70.96 | 16.05 | 12.99 |
| 70.96 | 17.24 | 11.80 |
| 70.94 | 18.63 | 10.43 |
| 70.87 | 18.97 | 10.16 |
| 70.58 | 19.40 | 10.02 |
| 70.18 | 19.74 | 10.08 |
| 69.39 | 20.01 | 10.60 |
| 68.48 | 20.21 | 11.31 |
| 67.77 | 20.26 | 11.98 |
| 66.98 | 20.26 | 12.76 |
| 66.13 | 20.21 | 13.66 |
| 66.08 | 20.09 | 13.82 |
| 65.98 | 19.75 | 14.27 |

In further embodiments, an exemplary glass can be described by a Convex Hull defined by the space made up by Table 2 above with SiO₂, a group named Al2O3_B2O3, and the remaining constituents into a group named RO, which contains MgO, CaO, SrO, BaO, SnO₂, and the other oxides listed in their respective ranges. A ternary space can then be defined by the space which boundary is set by the compositions of Table 2 in mole percent and as shown in FIG. 4. Table 6 below provides compositions (in mole percent) that define the boundary of the Convex Hull for the range defined by Table 2.

TABLE 6

| SiO2 | Al2O3_B2O3 | RO |
|---|---|---|
| 67.02 | 19.13 | 13.85 |
| 66.96 | 18.95 | 14.09 |
| 66.92 | 18.72 | 14.35 |
| 66.91 | 17.80 | 15.29 |
| 66.92 | 16.47 | 16.62 |
| 66.98 | 16.22 | 16.80 |
| 67.07 | 16.02 | 16.91 |
| 67.14 | 15.92 | 16.94 |
| 69.41 | 15.89 | 14.70 |
| 70.15 | 15.90 | 13.95 |
| 70.32 | 15.97 | 13.72 |
| 70.42 | 16.12 | 13.47 |
| 70.46 | 16.38 | 13.16 |
| 70.44 | 16.79 | 12.78 |
| 70.39 | 16.99 | 12.62 |
| 70.08 | 17.73 | 12.19 |
| 69.07 | 18.72 | 12.21 |
| 68.20 | 19.16 | 12.64 |
| 67.13 | 19.21 | 13.66 |
| 67.06 | 19.20 | 13.73 |

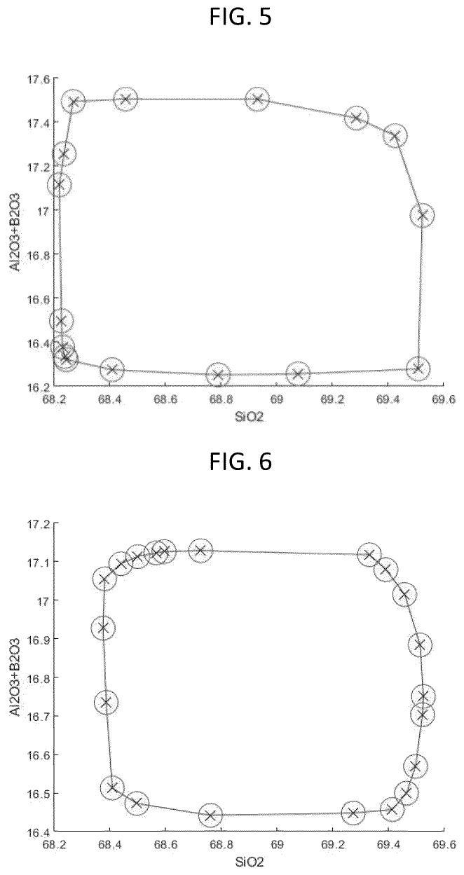

In additional embodiments, an exemplary glass can be described by a Convex Hull defined by the space made up by Table 3 above with SiO₂, a group named Al2O3_B2O3, and the remaining constituents into a group named RO, which contains MgO, CaO, SrO, BaO, SnO₂, and the other oxides listed in their respective ranges. A ternary space can then be defined by the space which boundary is set by the compositions of Table 3 in mole percent and as shown in FIG. 5. Table 7 below provides compositions (in mole percent) that define the boundary of the Convex Hull for the range defined by Table 3.

TABLE 7

| SiO2 | Al2O3_B2O3 | RO |
|---|---|---|
| 68.23 | 16.50 | 15.28 |
| 68.23 | 16.38 | 15.39 |
| 68.24 | 16.33 | 15.43 |
| 68.24 | 16.32 | 15.44 |
| 68.41 | 16.28 | 15.32 |
| 68.79 | 16.25 | 14.96 |
| 69.08 | 16.26 | 14.67 |
| 69.51 | 16.28 | 14.21 |
| 69.52 | 16.98 | 13.50 |
| 69.43 | 17.34 | 13.24 |
| 69.29 | 17.42 | 13.29 |
| 68.93 | 17.50 | 13.57 |
| 68.46 | 17.50 | 14.04 |
| 68.27 | 17.49 | 14.24 |
| 68.24 | 17.26 | 14.51 |
| 68.22 | 17.11 | 14.67 |

In some embodiments, an exemplary glass can be described by a Convex Hull defined by the space made up by Table 4 above with SiO₂, a group named Al2O3_B2O3, and the remaining constituents into a group named RO, which contains MgO, CaO, SrO, BaO, SnO₂, and the other oxides listed in their respective ranges. A ternary space can then be defined by the space which boundary is set by the compositions of Table 4 in mole percent and as shown in FIG. 6. Table 8 below provides compositions (in mole percent) that define the boundary of the Convex Hull for the range defined by Table 4.

TABLE 8

| SiO2 | Al2O3_B2O3 | RO |
|---|---|---|
| 68.39 | 16.73 | 14.88 |
| 68.41 | 16.51 | 15.08 |
| 68.50 | 16.47 | 15.03 |
| 68.76 | 16.44 | 14.80 |
| 69.27 | 16.45 | 14.28 |
| 69.41 | 16.46 | 14.13 |
| 69.46 | 16.50 | 14.04 |
| 69.50 | 16.57 | 13.93 |
| 69.52 | 16.70 | 13.78 |
| 69.52 | 16.75 | 13.73 |
| 69.51 | 16.88 | 13.60 |
| 69.46 | 17.01 | 13.53 |
| 69.39 | 17.08 | 13.53 |
| 69.33 | 17.12 | 13.55 |
| 68.73 | 17.13 | 14.15 |
| 68.59 | 17.13 | 14.28 |
| 68.56 | 17.12 | 14.31 |
| 68.50 | 17.11 | 14.39 |
| 68.44 | 17.09 | 14.47 |
| 68.38 | 17.06 | 14.56 |
| 68.38 | 16.93 | 14.70 |

Equations can then be generated in terms of attributes for such exemplary compositional embodiments. For example, Equation 1 below provides a suitable range of exemplary glasses in mole percent having a high liquidus viscosity and a viscosity curve which meets a certain threshold of customer facing attributes such as, but not limited to

$$70 G Pa \leq 549.899 - 4.811 * {SiO}_{2} - 4.023 * {Al}_{2} {O}_{3} - 5.651 * {B}_{2} {O}_{3} - 4.004 * MgO - 4.453 * CaO - 4.753 * SrO - 5.041 * BaO \leq 90 G Pa \qquad ( 1 )$$

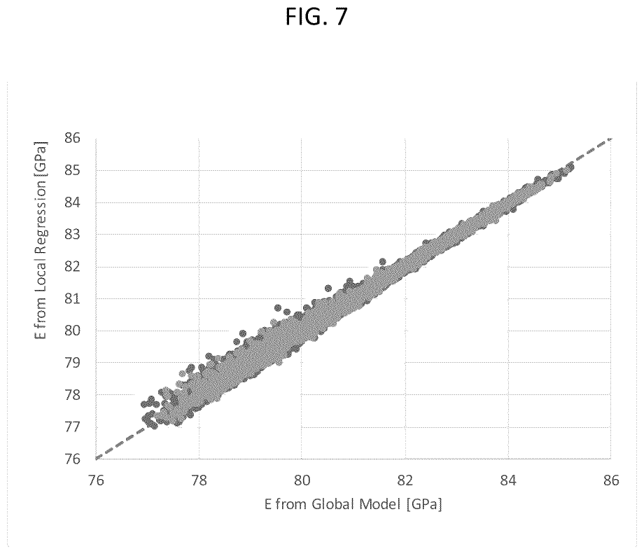

FIG. 7 is a graphical representation of Equation (1) for 20000 compositions randomly chosen inside the Convex Hull of FIG. 3 delimited by the composition boundary shown in Table 5.

By way of a further non-limiting example, Equation 2 below provides a suitable range of exemplary glasses in mole percent having a high liquidus viscosity and a viscosity curve which meets a certain threshold of customer facing attributes such as, but not limited to Annealing Point:

$$720 °C . \leq 1464.862 - 6.339 * {SiO}_{2} - 1.286 * {Al}_{2} {O}_{3} - 17.284 * {B}_{2} {O}_{3} - 12.216 * MgO - 11.448 * CaO - 11.367 * SrO - 12.832 * BaO \leq 810 °C . \qquad ( 2 )$$

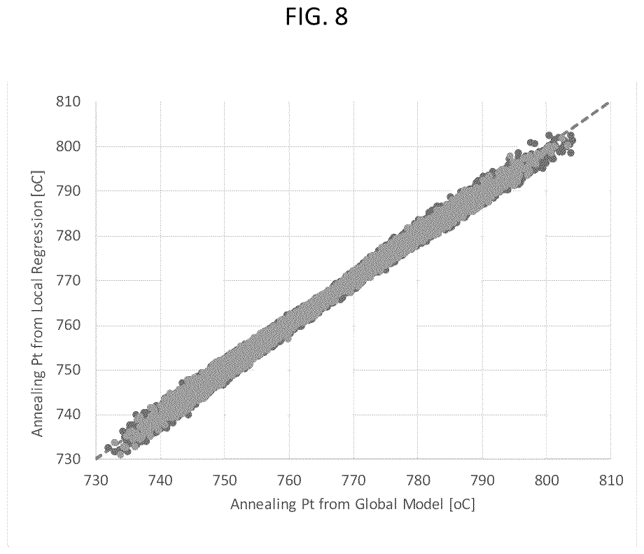

FIG. 8 is a graphical representation of Equation (2) for 20000 compositions randomly chosen inside the Convex Hull of FIG. 3 delimited by the composition boundary shown in Table 5.

Of course, such examples should not limit the scope of the claims appended herewith as one of skill in the art may define additional the compositional constituents of exemplary glasses as a function of further customer facing attributes.

Some embodiments provide a glass substantially free of alkalis comprising, in mole percent on an oxide basis: SiO₂: 66-70.5, Al₂O₃: 11.2-13.3, B₂O₃: 2.5-6, MgO: 2.5-6.3, CaO 2.7-8.3, SrO 1-5.8, BaO 0-3, wherein SiO₂, Al₂O₃, B₂O₃, MgO, CaO, SrO and BaO represent the mole percents of the oxide components. Further embodiments include a RO/Al2O₃ ratio of 0.98≤(MgO+CaO+SrO+BaO)/Al₂O₃≤1.38 or an Mg/RO ratio of 0.18≤MgO/(MgO+CaO+SrO+BaO)≤0.45. Some embodiments may also contain 0.01 to 0.4 mol % of any one or combination of SnO₂, As₂O₃, or Sb₂O₃, F, Cl or Br as a chemical fining agent. Some embodiments may also contain 0.005 to 0.2 mol % of any one of combination of Fe₂O₃, CeO₂, or MnO₂ as a chemical fining agent. Some embodiments may have an annealing point greater than 750° C., greater than 765° C., or greater than 770° C. Some embodiments may have a liquidus viscosity greater than 100,000 Poise, greater than 150,000 Poise, or greater than 180,000 Poise. Some embodiments may have a Young's Modulus of greater than 80 GPa, greater than 81 GPa, or greater than 81.5 GPa. Some embodiments may have a density less than 2.55 g/cc, less than 2.54 g/cc, or less than 2.53 g/cc. Some embodiments may have a T200P less than 1665° C., less than 1650° C., or less than 1640° C. Some embodiments may have a T35kP less than 1280° C., less than 1270° C., or less than 1266° C. Some embodiments may have a T200P−T(ann) less than 890° C., less than 880° C., less than 870° C., or less than 865° C. Some embodiments may have a T200P−T(ann) less than 890° C., T(ann)≥750° C., Young's Modulus of greater than 80 GPa, a density less than 2.55 g/cc, and a liquidus viscosity of greater than 100,000 Poise. Some embodiments may have a T200P−T(ann) less than 880° C., T(ann)≥765° C., Young's Modulus of greater than 81 GPa, a density less than 2.54 g/cc, and a liquidus viscosity of greater than 150,000 Poise. Some embodiments may have a T200P−T(ann) less than 865° C., T(ann)≥770° C., Young's Modulus of greater than 81.5 GPa, a density less than 2.54 g/cc, and a liquidus viscosity of greater than 180,000 Poise. In some embodiments, As₂O₃ and Sb₂O₃ comprise less than about 0.005 mol %. In some embodiments, Li₂O, Na₂O, K₂O, or combinations thereof, comprise less than about 0.1 mol % of the glass. In some embodiments, the raw materials comprise between 0 and 200 ppm sulfur by weight for each raw material employed. Exemplary objects comprising these glasses can be produced by a downdraw sheet fabrication process or a fusion process or a variant thereof.

Some embodiments provide a glass substantially free of alkalis comprising, in mole percent on an oxide basis: SiO₂: 68-79.5, Al₂O₃: 12.2-13, B₂O₃: 3.5-4.8, MgO: 3.7-5.3, CaO 4.7-7.3, SrO 1.5-4.4, BaO 0-2, where SiO2, Al2O3, B2O3, MgO, CaO, SrO and BaO represent the mole percents of the oxide components. Further embodiments include a RO/Al2O3 ratio of 1.07≤(MgO+CaO+SrO+BaO)/Al2O3≤1.2 or an MgO/RO ratio of 0.24≤MgO/(MgO+CaO+SrO+BaO)≤0.36. Some embodiments may also contain 0.01 to 0.4 mol % of any one or combination of SnO₂, As₂O₃, or Sb₂O₃, F, Cl or Br as a chemical fining agent. Some embodiments may also contain 0.005 to 0.2 mol % of any one of combination of Fe₂O₃, CeO₂, or MnO₂ as a chemical fining agent. Some embodiments may have a T200P−T(ann) less than 890° C., T(ann)≥750° C., Young's Modulus of greater than 80 GPa, a density less than 2.55 g/cc, and a liquidus viscosity of greater than 100,000 Poise. Some embodiments may have a T200P−T(ann) less than 880° C., T(ann)≥765° C., Young's Modulus of greater than 81 GPa, a density less than 2.54 g/cc, and a liquidus viscosity of greater than 150,000 Poise. Some embodiments may have a T200P−T(ann) less than 865° C., T(ann)≥770° C., Young's Modulus of greater than 81.5 GPa, a density less than 2.54 g/cc, and a liquidus viscosity of greater than 180,000 Poise. In some embodiments, As₂O₃ and Sb₂O₃ comprise less than about 0.005 mol %. In some embodiments, Li₂O, Na₂O, K₂O, or combinations thereof, comprise less than about 0.1 mol % of the glass. In some embodiments, the raw materials comprise between 0 and 200 ppm sulfur by weight for each raw material employed. Exemplary objects comprising these glasses can be produced by a downdraw sheet fabrication process or a fusion process or a variant thereof.

Some embodiments provide a glass substantially free of alkalis comprising, in mole percent on an oxide basis: SiO₂: 68.3-69.5, Al₂O₃: 12.4-13, B₂O₃: 3.7-4.5, MgO: 4-4.9, CaO 5.2-6.8, SrO 2.5-4.2, BaO 0-1, where SiO₂, Al₂O₃, B₂O₃, MgO, CaO, SrO and BaO represent the mole percents of the oxide components. Further embodiments include a RO/Al2O3 ratio of 1.09≤(MgO+CaO+SrO+BaO)/Al2O3≤1.16 or an MgO/RO ratio of 0.25≤MgO/(MgO+CaO+SrO+BaO)≤0.35. Some embodiments may also contain 0.01 to 0.4 mol % of any one or combination of SnO₂, As₂O₃, or Sb₂O₃, F, Cl or Br as a chemical fining agent. Some embodiments may also contain 0.005 to 0.2 mol % of any one of combination of Fe₂O₃, CeO₂, or MnO₂ as a chemical fining agent. Some embodiments may have a T200P−T(ann) less than 890° C., T(ann)≥750° C., Young's Modulus of greater than 80 GPa, a density less than 2.55 g/cc, and a liquidus viscosity of greater than 100,000 Poise. Some embodiments may have a T200P−T(ann) less than 880° C., T(ann)≥765° C., Young's Modulus of greater than 81 GPa, a density less than 2.54 g/cc, and a liquidus viscosity of greater than 150,000 Poise. Some embodiments may have a T200P−T(ann) less than 865° C., T(ann)≥770° C., Young's Modulus of greater than 81.5 GPa, a density less than 2.54 g/cc, and a liquidus viscosity of greater than 180,000 Poise. In some embodiments, As₂O₃ and Sb₂O₃ comprise less than about 0.005 mol %. In some embodiments, Li₂O, Na₂O, K₂O, or combinations thereof, comprise less than about 0.1 mol % of the glass. In some embodiments, the raw materials comprise between 0 and 200 ppm sulfur by weight for each raw material employed. Exemplary objects comprising these glasses can be produced by a downdraw sheet fabrication process or a fusion process or a variant thereof.

Some embodiments provide a glass having a Young's modulus in the range defined by the relationship: 70 GPa≤549.899-4.811*SiO₂-4.023*Al₂O₃-5.651*B₂O₃-4.004*MgO-4.453*CaO-4.753*SrO-5.041*BaO≤90 GPa, where SiO2, Al2O3, B2O3, MgO, CaO, SrO and BaO represent the mole percents of the oxide components. Further embodiments include a RO/Al2O3 ratio of 1.07≤(MgO+CaO+SrO+BaO)/Al₂O3≤1.2. Some embodiments may also contain 0.01 to 0.4 mol % of any one or combination of SnO₂, As₂O₃, or Sb₂O₃, F, Cl or Br as a chemical fining agent. Some embodiments may also contain 0.005 to 0.2 mol % of any one of combination of Fe₂O₃, CeO₂, or MnO₂ as a chemical fining agent. In some embodiments, As₂O₃ and Sb₂O₃ comprise less than about 0.005 mol %. In some embodiments, Li₂O, Na₂O, K₂O, or combinations thereof, comprise less than about 0.1 mol % of the glass. In some embodiments, the raw materials comprise between 0 and 200 ppm sulfur by weight for each raw material employed. Exemplary objects comprising these glasses can be produced by a downdraw sheet fabrication process or a fusion process or a variant thereof.

Some embodiments provide a glass having an Annealing Point in the range defined by the relationship: 720° C.≤1464.862-6.339*SiO₂-1.286*Al₂O₃-17.284*B₂O₃-12.216*MgO-11.448*CaO-11.367*SrO-12.832*BaO≤810° C., where SiO2, Al2O3, B2O3, MgO, CaO, SrO and BaO represent the mole percents of the oxide components. Further embodiments include a RO/Al2O3 ratio of 1.07≤(MgO+CaO+SrO+BaO)/Al2O3<1.2. Some embodiments may also contain 0.01 to 0.4 mol % of any one or combination of SnO₂, As₂O₃, or Sb₂O₃, F, Cl or Br as a chemical fining agent. Some embodiments may also contain 0.005 to 0.2 mol % of any one of combination of Fe₂O₃, CeO₂, or MnO₂ as a chemical fining agent. In some embodiments, As₂O₃ and Sb₂O₃ comprise less than about 0.005 mol %. In some embodiments, Li₂O, Na₂O, K₂O, or combinations thereof, comprise less than about 0.1 mol % of the glass. In some embodiments, the raw materials comprise between 0 and 200 ppm sulfur by weight for each raw material employed. Exemplary objects comprising these glasses can be produced by a downdraw sheet fabrication process or a fusion process or a variant thereof.

It will be appreciated that the various disclosed embodiments may involve particular features, elements or steps that are described in connection with that particular embodiment. It will also be appreciated that a particular feature, element or step, although described in relation to one particular embodiment, may be interchanged or combined with alternate embodiments in various non-illustrated combinations or permutations.

It is also to be understood that, as used herein the terms “the,” “a,” or “an,” mean “at least one,” and should not be limited to “only one” unless explicitly indicated to the contrary.

Ranges can be expressed herein as from “about” one particular value, and/or to “about” another particular value. When such a range is expressed, examples include from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

The terms “substantial,” “substantially,” and variations thereof as used herein are intended to note that a described feature is equal or approximately equal to a value or description.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to an apparatus that comprises A+B+C include embodiments where an apparatus consists of A+B+C and embodiments where an apparatus consists essentially of A+B+C.

It will be apparent to those skilled in the art that various modifications and variations can be made to the present disclosure without departing from the spirit and scope of the disclosure. Since modifications combinations, sub-combinations and variations of the disclosed embodiments incorporating the spirit and substance of the disclosure may occur to persons skilled in the art, the disclosure should be construed to include everything within the scope of the appended claims and their equivalents.

### EXAMPLES

The following examples are set forth below to illustrate the methods and results according to the disclosed subject matter. These examples are not intended to be inclusive of all embodiments of the subject matter disclosed herein, but rather to illustrate representative methods and results. These examples are not intended to exclude equivalents and variations of the disclosure which are apparent to one skilled in the art.

Efforts have been made to ensure accuracy with respect to numbers (e.g., amounts, temperature, etc.) but some errors and deviations should be accounted for. Unless indicated otherwise, temperature is in ° C. or is at ambient temperature, and pressure is at or near atmospheric. The compositions themselves are given in mole percent on an oxide basis and have been normalized to 100%. There are numerous variations and combinations of reaction conditions, e.g., component concentrations, temperatures, pressures and other reaction ranges and conditions that can be used to optimize the product purity and yield obtained from the described process. Only reasonable and routine experimentation will be required to optimize such process conditions.

The glass properties set forth in the tables herein were determined in accordance with techniques conventional in the glass art. Thus, the linear coefficient of thermal expansion (CTE) over the temperature range 25-300° C. is expressed in terms of ×10-7/° C. and the annealing point is expressed in terms of ° C. These were determined from fiber elongation techniques (ASTM references E228-85 and C336, respectively). The density in terms of grams/cm3 was measured via the Archimedes method (ASTM C693). The melting temperature in terms of ° C. (defined as the temperature at which the glass melt demonstrates a viscosity of 200 poises) was calculated employing a Fulcher equation fit to high temperature viscosity data measured via rotating cylinders viscometry (ASTM C965-81).

The liquidus temperature of the glass in terms of ° C. was measured using an isothermal liquidus method. This involves placing crushed glass particles in a small platinum crucible, placing the crucible in a furnace with a tightly controlled temperature variation, and heating the crucible at the temperature of interest for 24 hrs. After heating the crucible is air quenched and microscopic examination is utilized to determine the present crystalline phase(s) and the percentage of crystallinity within the interior of the glass. More particularly, the glass sample is removed from the Pt crucible in one piece, and examined using polarized light microscopy to identify the location and nature of crystals which have formed against the Pt and air interfaces, and in the interior of the sample. Samples are run through this process at multiple temperatures intended to bracket the actual liquidus temperature of the glass. Once the crystalline phase and percent crystallinity is identified at various temperatures, those temperatures can be used to identify the zero-crystal temperature, or the liquidus temperature, of the composition of interest. Testing is sometimes carried out at longer times (e.g., 72 hours), in order to observe slower growing phases. The crystalline phase for the various glasses of Table 9 are described by the following abbreviations: anor—anorthite, a calcium aluminosilicate mineral; cris—cristobalite (SiO₂); cels—mixed alkaline earth celsian; Sr/Al sil—a strontium aluminosilicate phase; SrSi—a strontium silicate phase. The liquidus viscosity in poises was determined from the liquidus temperature and the coefficients of the Fulcher equation.

Young's modulus values in terms of GPa were determined using a resonant ultrasonic spectroscopy technique of the general type set forth in ASTM E1875-00e1.

Exemplary glasses are provided in Table 9. As can be seen in Table 9, the exemplary glasses can have density, CTE, annealing point and Young's modulus values that make the glasses suitable for display applications, such as AMLCD substrate applications, and more particularly for low-temperature polysilicon and oxide thin film transistor applications. Although not shown in the tables herein, the glasses have durabilities in acid and base media that are similar to those obtained from commercial AMLCD substrates, and thus are appropriate for AMLCD applications. The exemplary glasses can be formed using downdraw techniques, and in particular are compatible with the fusion process, via the aforementioned criteria.

The exemplary glasses of the tables herein can be prepared using a commercial sand as a silica source, milled such that 90% by weight passed through a standard U.S. 100 mesh sieve. Alumina was the alumina source, periclase was the source for MgO, limestone the source for CaO, strontium carbonate, strontium nitrate or a mix thereof was the source for SrO, barium carbonate was the source for BaO, and tin (IV) oxide was the source for SnO₂. The raw materials were thoroughly mixed, loaded into a platinum vessel suspended in a furnace heated by silicon carbide glowbars, melted and stirred for several hours at temperatures between 160° and 1650° C. to ensure homogeneity, and delivered through an orifice at the base of the platinum vessel. The resulting patties of glass were annealed at or near the annealing point, and then subjected to various experimental methods to determine physical, viscous and liquidus attributes.

The glasses of the tables herein can be prepared using standard methods well-known to those skilled in the art. Such methods include a continuous melting process, such as would be performed in a continuous melting process, wherein the melter used in the continuous melting process is heated by gas, by electric power, or combinations thereof.

Raw materials appropriate for producing an exemplary glass include commercially available sands as sources for SiO₂; alumina, aluminum hydroxide, hydrated forms of alumina, and various aluminosilicates, nitrates and halides as sources for Al₂O₃; boric acid, anhydrous boric acid and boric oxide as sources for B₂O₃; periclase, dolomite (also a source of CaO), magnesia, magnesium carbonate, magnesium hydroxide, and various forms of magnesium silicates, aluminosilicates, nitrates and halides as sources for MgO; limestone, aragonite, dolomite (also a source of MgO), wolastonite, and various forms of calcium silicates, aluminosilicates, nitrates and halides as sources for CaO; and oxides, carbonates, nitrates and halides of strontium and barium. If a chemical fining agent is desired, tin can be added as SnO₂, as a mixed oxide with another major glass component (e.g., CaSnO₃), or in oxidizing conditions as SnO, tin oxalate, tin halide, or other compounds of tin known to those skilled in the art.

The glasses in the tables herein contain SnO₂ as a fining agent, but other chemical fining agents could also be employed to obtain glass of sufficient quality for TFT substrate applications. For example, exemplary glasses could employ any one or combinations of As₂O₃, Sb₂O₃, CeO₂, Fe₂O₃, and halides as deliberate additions to facilitate fining, and any of these could be used in conjunction with the SnO2 chemical fining agent shown in the examples. Of these, As₂O₃ and Sb₂O₃ are generally recognized as hazardous materials, subject to control in waste streams such as might be generated in the course of glass manufacture or in the processing of TFT panels. It is therefore desirable to limit the concentration of As₂O₃ and Sb₂O₃ individually or in combination to no more than 0.005 mole percent.

In addition to the elements deliberately incorporated into exemplary glasses, nearly all stable elements in the periodic table are present in glasses at some level, either through low levels of contamination in the raw materials, through high-temperature erosion of refractories and precious metals in the manufacturing process, or through deliberate introduction at low levels to fine tune the attributes of the final glass. For example, zirconium may be introduced as a contaminant via interaction with zirconium-rich refractories. As a further example, platinum and rhodium may be introduced via interactions with precious metals. As a further example, iron may be introduced as a tramp in raw materials, or deliberately added to enhance control of gaseous inclusions. As a further example, manganese may be introduced to control color or to enhance control of gaseous inclusions. As a further example, alkalis may be present as a tramp component at levels up to about 0.1 mole percent for the combined concentration of Li₂O, Na₂O and K₂O.

Hydrogen is inevitably present in the form of the hydroxyl anion, OH-, and its presence can be ascertained via standard infrared spectroscopy techniques. Dissolved hydroxyl ions significantly and nonlinearly impact the annealing point of exemplary glasses, and thus to obtain the desired annealing point it may be necessary to adjust the concentrations of major oxide components so as to compensate. Hydroxyl ion concentration can be controlled to some extent through choice of raw materials or choice of melting system. For example, boric acid is a major source of hydroxyls, and replacing boric acid with boric oxide can be a useful means to control hydroxyl concentration in the final glass. The same reasoning applies to other potential raw materials comprising hydroxyl ions, hydrates, or compounds comprising physisorbed or chemisorbed water molecules. If burners are used in the melting process, then hydroxyl ions can also be introduced through the combustion products from combustion of natural gas and related hydrocarbons, and thus it may be desirable to shift the energy used in melting from burners to electrodes to compensate. Alternatively, one might instead employ an iterative process of adjusting major oxide components so as to compensate for the deleterious impact of dissolved hydroxyl ions.

Sulfur is often present in natural gas, and likewise is a tramp component in many carbonate, nitrate, halide, and oxide raw materials. In the form of SO₂, sulfur can be a troublesome source of gaseous inclusions. The tendency to form SO₂-rich defects can be managed to a significant degree by controlling sulfur levels in the raw materials, and by incorporating low levels of comparatively reduced multivalent cations into the glass matrix. While not wishing to be bound by theory, it appears that SO₂-rich gaseous inclusions arise primarily through reduction of sulfate (SO₄⁼) dissolved in the glass. The elevated barium concentrations of exemplary glasses appear to increase sulfur retention in the glass in early stages of melting, but as noted above, barium is required to obtain low liquidus temperature, and hence high liquidus viscosity. Deliberately controlling sulfur levels in raw materials to a low level is a useful means of reducing dissolved sulfur (presumably as sulfate) in the glass. In particular, sulfur can be less than 200 ppm by weight in the batch materials, or less than 100 ppm by weight in the batch materials.

Reduced multivalents can also be used to control the tendency of exemplary glasses to form SO₂ blisters. While not wishing to be bound to theory, these elements behave as potential electron donors that suppress the electromotive force for sulfate reduction. Sulfate reduction can be written in terms of a half reaction such as

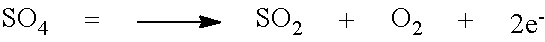

where e− denotes an electron. The “equilibrium constant” for the half reaction is

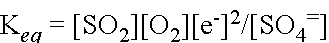

where the brackets denote chemical activities. Ideally one would like to force the reaction so as to create sulfate from SO₂, O₂ and 2e−. Adding nitrates, peroxides, or other oxygen-rich raw materials may help, but also may work against sulfate reduction in the early stages of melting, which may counteract the benefits of adding them in the first place. SO₂ has very low solubility in most glasses, and so is impractical to add to the glass melting process. Electrons may be “added” through reduced multivalents. For example, an appropriate electron-donating half reaction for ferrous iron (Fe²⁺) is expressed as

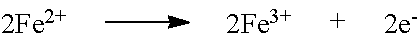

This “activity” of electrons can force the sulfate reduction reaction to the left, stabilizing SO₄═ in the glass. Suitable reduced multivalents include, but are not limited to, Fe²⁺, Mn²⁺, Sn²⁺, Sb³⁺, As³⁺, V³⁺, Ti³⁺, and others familiar to those skilled in the art. In each case, it may be important to minimize the concentrations of such components so as to avoid deleterious impact on color of the glass, or in the case of As and Sb, to avoid adding such components at a high enough level so as to complication of waste management in an end-user's process.

In addition to the major oxides components of exemplary glasses, and the minor or tramp constituents noted above, halides may be present at various levels, either as contaminants introduced through the choice of raw materials, or as deliberate components used to eliminate gaseous inclusions in the glass. As a fining agent, halides may be incorporated at a level of about 0.4 mole percent or less, though it is generally desirable to use lower amounts if possible to avoid corrosion of off-gas handling equipment. In some embodiments, the concentration of individual halide elements are below about 200 ppm by weight for each individual halide, or below about 800 ppm by weight for the sum of all halide elements.

In addition to these major oxide components, minor and tramp components, multivalents and halide fining agents, it may be useful to incorporate low concentrations of other colorless oxide components to achieve desired physical, optical or viscoelastic properties. Such oxides include, but are not limited to, TiO₂, ZrO₂, HfO₂, Nb₂O₅, Ta₂O₅, MoO₃, WO₃, ZnO, In₂O₃, Ga₂O₃, Bi₂O₃, GeO₂, PbO, SeO₃, TeO₂, Y₂O₃, La₂O₃, Gd₂O₃, and others known to those skilled in the art. Through an iterative process of adjusting the relative proportions of the major oxide components of exemplary glasses, such colorless oxides can be added to a level of up to about 2 mole percent without unacceptable impact to annealing point or liquidus viscosity.

Table 9 shows exemplary glasses according to some embodiments of the present disclosure.

TABLE 9

| Mol % | 1 | 2 | 3 | 4 | 5 | 6 | 7 | 8 |
|---|---|---|---|---|---|---|---|---|
| SiO2 | 67.71 | 68.6 | 68.91 | 67.76 | 68.32 | 68.73 | 68.62 | 69.41 |
| Al2O3 | 13.18 | 12.71 | 12.69 | 12.72 | 12.6 | 12.72 | 12.84 | 12.42 |
| B2O3 | 4.11 | 4.5 | 4.22 | 4.94 | 4.95 | 4.4 | 3.93 | 4.14 |
| MgO | 5.36 | 4.22 | 4.11 | 4.68 | 3.75 | 4.33 | 4.39 | 4.35 |
| CaO | 5.63 | 5.43 | 5.95 | 6.34 | 6.06 | 5.46 | 6.14 | 5.59 |
| SrO | 3.84 | 3.49 | 4 | 3.4 | 4.13 | 3.43 | 3.9 | 3.92 |
| BaO | 0.06 | 0.95 | 0 | 0.05 | 0.07 | 0.83 | 0.06 | 0.04 |
| SnO2 | 0.1 | 0.08 | 0.1 | 0.1 | 0.1 | 0.08 | 0.1 | 0.1 |
| Fe2O3 | 0.01 | 0.01 | 0.01 | 0.01 | 0.01 | 0.01 | 0.01 | 0.01 |
| ZrO2 | 0 | 0.02 | 0 | 0 | 0 | 0.01 | 0 | 0.02 |
| RO/Al2O3 | 1.13 | 1.11 | 1.11 | 1.14 | 1.11 | 1.1 | 1.13 | 1.12 |
| MgO/RO | [symbol] 0.36 | [symbol] 0.30 | [symbol] 0.29 | [symbol] 0.32 | [symbol] 0.27 | [symbol] 0.31 | [symbol] 0.30 | [symbol] 0.31 |
| Strain | 723 | 719 | 722 | 714 | 713 | 721 | 724 | 723 |
| Point (C.) | | | | | | | | |
| Anneal | 773 | 771 | 775 | 766 | 767 | 772 | 777 | 777 |
| Point (C.) | | | | | | | | |
| CTE | 34.6 | 34.9 | 34.5 | 34.5 | 34.9 | 34.6 | 34.8 | 34.1 |
| Density | 2.527 | 2.532 | 2.514 | 2.508 | 2.513 | 2.528 | 2.522 | 2.509 |
| Modulus | 83.2 | 81.2 | 81.7 | 81.7 | 80.7 | 81.4 | 82.3 | 81.6 |
| (GPa) | | | | | | | | |
| T (200) | 1602 | 1631 | 1630 | 1603 | 1621 | 1631 | 1622 | 1640 |
| T(35000) | 1246 | 1259 | 1260 | 1242 | 1252 | 1260 | 1257 | 1265 |
| Liquidus T | 1190 | 1180 | 1187 | 1183 | 1180 | 1180 | 1187 | 1190 |
| Liq | 1.18E+05 | 1.90E+05 | 1.66E+05 | 1.25E+05 | 1.61E+05 | 1.95E+05 | 1.56E+05 | 1.74E+05 |
| Viscosity | | | | | | | | |
| T200P − | 829 | 860 | 855 | 837 | 854 | 859 | 845 | 863 |
| T(ann) | | | | | | | | |
| Mol % | 9 | 10 | 11 | 12 | 13 | 14 | 15 | 16 |
| SiO2 | 68.58 | 69.4 | 69.33 | 69.22 | 68.61 | 68.44 | 69.13 | 67.94 |
| Al2O3 | 12.54 | 12.49 | 12.5 | 12.54 | 12.76 | 12.56 | 12.62 | 12.66 |
| B2O3 | 4.29 | 4.12 | 4.25 | 4.07 | 3.87 | 4.35 | 4.33 | 4.93 |
| MgO | 4.3 | 4.35 | 4.29 | 4.25 | 4.86 | 4.77 | 4.41 | 4.94 |
| CaO | 6.26 | 5.57 | 5.57 | 5.37 | 5.72 | 5.43 | 5.52 | 5.72 |
| SrO | 3.85 | 3.9 | 3.91 | 3.91 | 4 | 3.9 | 3.89 | 3.62 |
| BaO | 0.06 | 0.04 | 0.05 | 0.53 | 0.06 | 0.43 | 0 | 0.05 |
| SnO2 | 0.1 | 0.09 | 0.09 | 0.1 | 0.1 | 0.1 | 0.09 | 0.1 |
| Fe2O3 | 0.01 | 0.01 | 0.01 | 0.01 | 0.01 | 0.01 | 0.01 | 0.01 |
| ZrO2 | 0 | 0.02 | 0.01 | 0 | 0 | 0 | 0 | 0.02 |
| RO/Al2O3 | 1.15 | 1.11 | 1.11 | 1.12 | 1.15 | 1.16 | 1.1 | 1.13 |
| MgO/RO | [symbol] 0.30 | [symbol] 0.31 | [symbol] 0.31 | [symbol] 0.30 | [symbol] 0.33 | [symbol] 0.33 | [symbol] 0.32 | [symbol] 0.34 |
| Strain | 719 | 724 | 723 | 723 | 725 | 719 | 723 | 716 |
| Point (C.) | | | | | | | | |
| Anneal | 773 | 777 | 776 | 776 | 777 | 771 | 775 | 766 |
| Point (C.) | | | | | | | | |
| CTE | 35 | 34 | 34 | 34.7 | 34.7 | 35 | 33.9 | 34.3 |
| Density | 2.517 | 2.509 | 2.508 | 2.526 | 2.524 | 2.528 | 2.507 | 2.508 |
| Modulus | 81.7 | 81.6 | 81.5 | 81.5 | 82.6 | 81.8 | 81.6 | 81.7 |
| (GPa) | | | | | | | | |
| T (200) | 1620 | 1640 | 1638 | 1640 | 1621 | 1621 | 1634 | 1608 |
| T(35000) | 1253 | 1266 | 1265 | 1266 | 1256 | 1254 | 1262 | 1245 |
| Liquidus T | 1181 | 1185 | 1190 | 1182 | 1185 | 1200 | 1180 | 1180 |
| Liq | 1.66E+05 | 1.97E+05 | 1.71E+05 | 2.09E+05 | 1.63E+05 | 1.09E+05 | 2.06E+05 | 1.43E+05 |
| Viscosity | | | | | | | | |
| T200P − | 847 | 863 | 862 | 864 | 844 | 850 | 859 | 842 |
| T(ann) | | | | | | | | |
| Mol % | 17 | 18 | 19 | 20 | 21 | 22 | 23 | 24 |
| SiO2 | 69.09 | 68.39 | 68.92 | 68.82 | 69.51 | 68.77 | 69.66 | 68.52 |
| Al2O3 | 12.64 | 12.58 | 12.73 | 12.89 | 12.34 | 12.71 | 12.06 | 12.53 |
| B2O3 | 3.95 | 4.37 | 3.96 | 4.37 | 4.16 | 4.35 | 4.91 | 4.9 |
| MgO | 4.6 | 4.78 | 4.27 | 4.39 | 4.58 | 5.16 | 4.01 | 4.2 |
| CaO | 5.77 | 5.29 | 5.44 | 5.34 | 5.24 | 5.71 | 5.04 | 5.57 |
| SrO | 3.77 | 4.14 | 3.53 | 4.08 | 4.07 | 3.17 | 4.23 | 4.1 |
| BaO | 0.06 | 0.34 | 1.04 | 0 | 0 | 0.04 | 0 | 0.05 |
| SnO2 | 0.1 | 0.1 | 0.1 | 0.09 | 0.08 | 0.08 | 0.09 | 0.09 |
| Fe2O3 | 0.01 | 0.01 | 0.01 | 0.01 | 0.01 | 0.01 | 0.01 | 0.01 |
| ZrO2 | 0 | 0 | 0 | 0 | 0 | 0.01 | 0 | 0.03 |
| RO/Al2O3 | 1.12 | 1.16 | 1.12 | 1.07 | 1.13 | 1.11 | 1.1 | 1.11 |
| MgO/RO | [symbol] 0.32 | [symbol] 0.33 | [symbol] 0.30 | [symbol] 0.32 | [symbol] 0.33 | [symbol] 0.37 | [symbol] 0.30 | [symbol] 0.30 |
| Strain | 725 | 719 | 724 | 723 | 724 | 724 | 717 | 715 |
| Point (C.) | | | | | | | | |
| Anneal | 778 | 770 | 776 | 774 | 776 | 774 | 770 | 767 |
| Point (C.) | | | | | | | | |
| CTE | 34.2 | 35 | 35.1 | 33.9 | 34 | 33.4 | 33.8 | 34.4 |
| Density | 2.514 | 2.529 | 2.541 | 2.512 | 2.508 | 2.501 | 2.497 | 2.51 |
| Modulus | 82.2 | 81.8 | 81.7 | 81.8 | 81.6 | 82.3 | 80.2 | 80.9 |
| (GPa) | | | | | | | | |
| T (200) | 1631 | 1621 | 1636 | 1630 | 1641 | 1620 | 1648 | 1625 |
| T(35000) | 1262 | 1253 | 1264 | 1261 | 1266 | 1256 | 1267 | 1254 |
| Liquidus T | 1200 | 1200 | 1180 | 1210 | 1210 | 1200 | 1205 | 1180 |
| Liq | 1.29E+05 | 1.08E+05 | 2.13E+05 | 1.01E+05 | 1.12E+05 | 1.14E+05 | 1.25E+05 | 1.71E+05 |
| Viscosity | | | | | | | | |
| T200P − | 853 | 851 | 860 | 856 | 865 | 846 | 878 | 858 |
| T(ann) | | | | | | | | |
| Mol % | 25 | 26 | 27 | 28 | 29 | 30 | 31 | 32 |
| SiO2 | 68.67 | 69.21 | 68.84 | 69.3 | 67.44 | 67.74 | 68.53 | 68.86 |
| Al2O3 | 12.71 | 12.5 | 12.69 | 12.49 | 13.02 | 12.51 | 12.54 | 12.87 |
| B2O3 | 4.46 | 4.04 | 4.37 | 4.19 | 4.77 | 4.48 | 4.34 | 4.28 |
| MgO | 4.28 | 4.41 | 4.54 | 4.4 | 4.91 | 5.11 | 4.72 | 4.34 |
| CaO | 5.44 | 5.56 | 5.52 | 5.59 | 6.42 | 5.63 | 5.46 | 5.38 |
| SrO | 3.45 | 4.12 | 3.33 | 3.85 | 3.27 | 4.35 | 3.79 | 4.15 |
| BaO | 0.88 | 0.06 | 0.6 | 0.04 | 0.05 | 0.07 | 0.51 | 0 |
| SnO2 | 0.08 | 0.1 | 0.09 | 0.1 | 0.1 | 0.1 | 0.1 | 0.09 |
| Fe2O3 | 0.01 | 0.01 | 0.01 | 0.01 | 0.01 | 0.01 | 0.01 | 0.01 |
| ZrO2 | 0.02 | 0 | 0.02 | 0.02 | 0 | 0 | 0 | 0 |
| RO/Al2O3 | 1.11 | 1.13 | 1.1 | 1.11 | 1.13 | 1.21 | 1.15 | 1.08 |
| MgO/RO | [symbol] 0.30 | [symbol] 0.31 | [symbol] 0.32 | [symbol] 0.32 | [symbol] 0.34 | [symbol] 0.34 | [symbol] 0.33 | [symbol] 0.31 |
| Strain | 720 | 723 | 722 | 723 | 717 | 716 | 720 | 723 |
| Point (C.) | | | | | | | | |
| Anneal | 772 | 776 | 773 | 776 | 767 | 766 | 771 | 775 |
| Point (C.) | | | | | | | | |
| CTE | 34.7 | 34.5 | 34.2 | 34 | 34.5 | 35.6 | 34.9 | 34.1 |
| Density | 2.529 | 2.517 | 2.519 | 2.508 | 2.512 | 2.53 | 2.528 | 2.514 |
| Modulus | 81.3 | 81.8 | 81.6 | 81.6 | 82.3 | 82.1 | 81.7 | 81.9 |
| (GPa) | | | | | | | | |
| T (200) | 1632 | 1635 | 1630 | 1637 | 1595 | 1603 | 1623 | 1631 |
| T(35000) | 1260 | 1263 | 1260 | 1264 | 1240 | 1243 | 1255 | 1261 |
| Liquidus T | 1180 | 1183 | 1184 | 1182 | 1181 | 1180 | 1195 | 1190 |
| Liq | 1.93E+05 | 1.95E+05 | 1.79E+05 | 2.05E+05 | 1.25E+05 | 1.35E+05 | 1.24E+05 | 1.60E+05 |
| Viscosity | | | | | | | | |
| T200P − | 860 | 859 | 857 | 861 | 828 | 837 | 852 | 856 |
| T(ann) | | | | | | | | |
| Mol % | 33 | 34 | 35 | 36 | 37 | 38 | 39 | 40 |
| SiO2 | 68.78 | 68.25 | 69.01 | 67.39 | 68.98 | 68.97 | 70.37 | 69.38 |
| Al2O3 | 12.92 | 12.76 | 12.5 | 13.03 | 12.67 | 12.49 | 12.04 | 12.49 |
| B2O3 | 4.24 | 4.78 | 4.47 | 5.02 | 4.92 | 4.42 | 4.36 | 4.12 |
| MgO | 4.34 | 4.34 | 4.26 | 4.62 | 3.79 | 4.52 | 3.93 | 4.35 |
| CaO | 5.43 | 6.75 | 5.58 | 6.37 | 5.32 | 5.62 | 4.98 | 5.59 |
| SrO | 4.18 | 2.97 | 3.98 | 3.39 | 4.22 | 3.8 | 4.22 | 3.9 |
| BaO | 0 | 0.05 | 0.05 | 0.06 | 0 | 0.04 | 0 | 0.04 |
| SnO2 | 0.09 | 0.09 | 0.11 | 0.1 | 0.09 | 0.11 | 0.08 | 0.09 |
| Fe2O3 | 0.01 | 0.01 | 0.01 | 0.02 | 0.01 | 0.01 | 0.01 | 0.01 |
| ZrO2 | 0 | 0 | 0.03 | 0 | 0 | 0.03 | 0 | 0.02 |
| RO/Al2O3 | 1.08 | 1.11 | 1.11 | 1.11 | 1.05 | 1.12 | 1.09 | 1.11 |
| MgO/RO | [symbol] 0.31 | [symbol] 0.31 | [symbol] 0.31 | [symbol] 0.32 | [symbol] 0.28 | [symbol] 0.32 | [symbol] 0.30 | [symbol] 0.31 |
| Strain | 723 | 717 | 720 | 714 | 717 | 721 | 723 | 724 |
| Point (C.) | | | | | | | | |
| Anneal | 775 | 770 | 773 | 765 | 770 | 773 | 777 | 777 |
| Point (C.) | | | | | | | | |
| CTE | 34.2 | 34.1 | 34.2 | 34.5 | 33.9 | 34.1 | 33.5 | 34.1 |
| Density | 2.516 | 2.499 | 2.509 | 2.51 | 2.504 | 2.507 | 2.498 | 2.509 |
| Modulus | 82 | 81.6 | 81.3 | 81.9 | 80.7 | 81.5 | 80.5 | 81.6 |
| (GPa) | | | | | | | | |
| T (200) | 1629 | 1611 | 1634 | 1597 | 1637 | 1630 | 1663 | 1639 |
| T(35000) | 1260 | 1248 | 1261 | 1240 | 1262 | 1260 | 1277 | 1266 |
| Liquidus T | 1200 | 1187 | 1181 | 1161 | 1187 | 1180 | 1205 | 1185 |
| Liq | 1.25E+05 | 1.30E+05 | 1.94E+05 | 2.00E+05 | 1.71E+05 | 1.93E+05 | 1.55E+05 | 1.96E+05 |
| Viscosity | | | | | | | | |
| T200P − | 854 | 841 | 861 | 832 | 867 | 857 | 886 | 862 |
| T(ann) | | | | | | | | |
| Mol % | 41 | 42 | 43 | 44 | 45 | 46 | 47 | 48 |
| SiO2 | 68.88 | 69.2 | 68.73 | 69.56 | 69.06 | 68.24 | 69.34 | 67.8 |
| Al2O3 | 12.41 | 12.46 | 12.71 | 12.32 | 12.61 | 12.6 | 12.56 | 12.72 |
| B2O3 | 4.44 | 3.83 | 4.4 | 4.16 | 4.23 | 4.95 | 4.11 | 4.96 |
| MgO | 4.51 | 4.54 | 4.17 | 4.57 | 4.41 | 4.6 | 4.39 | 4.67 |
| CaO | 5.48 | 5.44 | 5.41 | 5.24 | 5.63 | 5.64 | 5.56 | 6.01 |
| SrO | 3.44 | 4.34 | 3.49 | 4.06 | 3.95 | 3.83 | 3.92 | 3.67 |
| BaO | 0.73 | 0.07 | 0.97 | 0 | 0 | 0.04 | 0 | 0.06 |
| SnO2 | 0.1 | 0.12 | 0.08 | 0.08 | 0.09 | 0.09 | 0.09 | 0.1 |
| Fe2O3 | 0.01 | 0.01 | 0.01 | 0.01 | 0.01 | 0.01 | 0.01 | 0.01 |
| ZrO2 | 0 | 0 | 0.02 | 0 | 0 | 0.01 | 0 | 0 |
| RO/Al2O3 | 1.14 | 1.15 | 1.1 | 1.13 | 1.11 | 1.12 | 1.1 | 1.13 |
| MgO/RO | [symbol] 0.32 | [symbol] 0.32 | [symbol] 0.30 | [symbol] 0.33 | [symbol] 0.32 | [symbol] 0.33 | [symbol] 0.32 | [symbol] 0.32 |
| Strain | 719 | 725 | 720 | 724 | 723 | 715 | 724 | 714 |
| Point (C.) | | | | | | | | |
| Anneal | 771 | 778 | 772 | 776 | 775 | 766 | 777 | 765 |
| Point (C.) | | | | | | | | |
| CTE | 34.7 | 34.8 | 34.9 | 34 | 34.2 | 34.3 | 34 | 34.6 |
| Density | 2.523 | 2.524 | 2.533 | 2.508 | 2.511 | 2.508 | 2.509 | 2.511 |
| Modulus | 81.2 | 82 | 81.2 | 81.5 | 81.8 | 81.3 | 81.8 | 81.6 |
| (GPa) | | | | | | | | |
| T (200) | 1632 | 1635 | 1634 | 1641 | 1632 | 1616 | 1638 | 1606 |
| T(35000) | 1259 | 1263 | 1261 | 1266 | 1261 | 1250 | 1265 | 1244 |
| Liquidus T | 1183 | 1187 | 1180 | 1205 | 1210 | 1180 | 1180 | 1180 |
| Liq | 1.79E+05 | 1.79E+05 | 1.99E+05 | 1.26E+05 | 1.02E+05 | 1.56E+05 | 2.19E+05 | 1.38E+05 |
| Viscosity | | | | | | | | |
| T200P − | 861 | 857 | 862 | 865 | 857 | 850 | 861 | 841 |
| T(ann) | | | | | | | | |
| Mol % | 49 | 50 | 51 | 52 | 53 | 54 | 55 | 56 |
| SiO2 | 67.71 | 69 | 68.79 | 67.91 | 68.94 | 69.06 | 68.47 | 68.37 |
| Al2O3 | 13.16 | 12.63 | 12.83 | 12.55 | 12.49 | 12.59 | 12.6 | 12.53 |
| B2O3 | 4.13 | 4.44 | 4.06 | 4.89 | 4.47 | 5.1 | 4.4 | 5.03 |
| MgO | 4.98 | 4.37 | 4.72 | 4.67 | 4.51 | 3.77 | 4.61 | 4.19 |
| CaO | 6.28 | 5.54 | 5.54 | 6.41 | 5.61 | 5.22 | 5.56 | 5.58 |
| SrO | 3.57 | 3.91 | 3.88 | 3.41 | 3.8 | 4.14 | 3.48 | 4.13 |
| BaO | 0.06 | 0 | 0.06 | 0.05 | 0.04 | 0 | 0.75 | 0.05 |
| SnO2 | 0.1 | 0.09 | 0.1 | 0.1 | 0.11 | 0.09 | 0.1 | 0.09 |
| Fe2O3 | 0.01 | 0.01 | 0.01 | 0.02 | 0.01 | 0.01 | 0.01 | 0.01 |
| ZrO2 | 0 | 0 | 0 | 0 | 0.03 | 0 | 0 | 0.03 |
| RO/Al2O3 | 1.13 | 1.09 | 1.11 | 1.16 | 1.12 | 1.04 | 1.14 | 1.11 |
| MgO/RO | [symbol] 0.33 | [symbol] 0.32 | [symbol] 0.33 | [symbol] 0.32 | [symbol] 0.32 | [symbol] 0.29 | [symbol] 0.32 | [symbol] 0.30 |
| Strain | 722 | 721 | 725 | 714 | 720 | 716 | 719 | 714 |
| Point (C.) | | | | | | | | |
| Anneal | 774 | 774 | 776 | 766 | 773 | 769 | 771 | 766 |
| Point (C.) | | | | | | | | |
| CTE | 34.8 | 34 | 34.2 | 34.7 | 34.1 | 33.6 | 34.9 | 34.5 |
| Density | 2.524 | 2.507 | 2.516 | 2.508 | 2.507 | 2.498 | 2.529 | 2.51 |
| Modulus | 83 | 81.5 | 82.3 | 81.5 | 81.5 | 80.4 | 81.6 | 80.8 |
| (GPa) | | | | | | | | |
| T (200) | 1601 | 1632 | 1626 | 1605 | 1630 | 1640 | 1624 | 1622 |
| T(35000) | 1245 | 1261 | 1259 | 1243 | 1259 | 1263 | 1255 | 1252 |
| Liquidus T | 1185 | 1187 | 1190 | 1175 | 1182 | 1200 | 1180 | 1180 |
| Liq | 1.29E+05 | 1.69E+05 | 1.54E+05 | 1.53E+05 | 1.83E+05 | 1.29E+05 | 1.76E+05 | 1.63E+05 |
| Viscosity | | | | | | | | |
| T200P − | 827 | 858 | 850 | 839 | 857 | 871 | 853 | 856 |
| T(ann) | | | | | | | | |
| Mol % | 57 | 58 | 59 | 60 | 61 | 62 | 63 | 64 |
| SiO2 | 69.27 | 67.95 | 69.16 | 68.45 | 68.74 | 67.7 | 67.79 | 68.31 |
| Al2O3 | 12.42 | 12.64 | 12.58 | 12.6 | 12.7 | 12.9 | 12.89 | 12.69 |
| B2O3 | 4.28 | 5 | 4.08 | 4.31 | 4.41 | 4.93 | 4.93 | 4.65 |
| MgO | 4.36 | 4.97 | 4.39 | 4.81 | 4.19 | 4.61 | 4.6 | 4.49 |
| CaO | 5.59 | 5.64 | 5.57 | 5.34 | 5.42 | 5.72 | 5.99 | 5.42 |
| SrO | 3.92 | 3.62 | 4.05 | 4.31 | 3.49 | 3.96 | 3.64 | 4.24 |
| BaO | 0.04 | 0.06 | 0.07 | 0.07 | 0.95 | 0.06 | 0.05 | 0.07 |
| SnO2 | 0.1 | 0.1 | 0.11 | 0.1 | 0.08 | 0.1 | 0.1 | 0.1 |
| Fe2O3 | 0.01 | 0.01 | 0.01 | 0.01 | 0.01 | 0.01 | 0.01 | 0.01 |
| ZrO2 | 0.02 | 0.02 | 0 | 0 | 0.02 | 0 | 0 | 0 |
| RO/Al2O3 | 1.12 | 1.13 | 1.12 | 1.15 | 1.11 | 1.11 | 1.11 | 1.12 |
| MgO/RO | [symbol] 0.31 | [symbol] 0.35 | [symbol] 0.31 | [symbol] 0.33 | [symbol] 0.30 | [symbol] 0.32 | [symbol] 0.32 | [symbol] 0.32 |
| Strain | 722 | 715 | 724 | 720 | 720 | 715 | 715 | 717 |
| Point (C.) | | | | | | | | |
| Anneal | 775 | 765 | 776 | 771 | 772 | 766 | 766 | 769 |
| Point (C.) | | | | | | | | |
| CTE | 34.1 | 34.2 | 34.4 | 34.9 | 34.8 | 34.6 | 34.4 | 34.6 |
| Density | 2.508 | 2.507 | 2.516 | 2.524 | 2.532 | 2.516 | 2.51 | 2.518 |
| Modulus | 81.5 | 81.6 | 81.8 | 81.9 | 81.2 | 81.7 | 81.7 | 81.5 |
| (GPa) | | | | | | | | |
| T (200) | 1637 | 1608 | 1634 | 1620 | 1633 | 1606 | 1606 | 1620 |
| T(35000) | 1263 | 1245 | 1263 | 1254 | 1261 | 1245 | 1245 | 1253 |
| Liquidus T | 1185 | 1180 | 1195 | 1180 | 1180 | 1180 | 1180 | 1180 |
| Liq | 1.86E+05 | 1.43E+05 | 1.47E+05 | 1.71E+05 | 1.98E+05 | 1.41E+05 | 1.41E+05 | 1.67E+05 |
| Viscosity | | | | | | | | |
| T200P − | 862 | 843 | 858 | 849 | 861 | 840 | 840 | 851 |
| T(ann) | | | | | | | | |
| Mol % | 65 | 66 | 67 | 68 | 69 | 70 | 71 | 72 |
| SiO2 | 68.99 | 68.55 | 68.36 | 68.81 | 68.92 | 69.1 | 67.57 | 69.05 |
| Al2O3 | 12.71 | 12.53 | 12.58 | 12.7 | 12.73 | 12.65 | 12.91 | 12.6 |
| B2O3 | 3.95 | 4.91 | 5.07 | 3.98 | 3.96 | 4.86 | 4.99 | 5.15 |
| MgO | 4.44 | 4.21 | 3.75 | 4.74 | 4.27 | 3.81 | 4.67 | 3.78 |
| CaO | 5.61 | 5.57 | 5.97 | 5.95 | 5.44 | 5.29 | 6.32 | 5.18 |
| SrO | 3.66 | 4.05 | 4.08 | 3.66 | 3.53 | 4.19 | 3.37 | 4.13 |
| BaO | 0.53 | 0.04 | 0.07 | 0.05 | 1.04 | 0 | 0.05 | 0 |
| SnO2 | 0.11 | 0.09 | 0.1 | 0.1 | 0.1 | 0.09 | 0.1 | 0.09 |
| Fe2O3 | 0.01 | 0.01 | 0.01 | 0.01 | 0.01 | 0.01 | 0.01 | 0.01 |
| ZrO2 | 0 | 0.03 | 0 | 0 | 0 | 0 | 0 | 0 |
| RO/Al2O3 | 1.12 | 1.11 | 1.1 | 1.13 | 1.12 | 1.05 | 1.12 | 1.04 |
| MgO/RO | [symbol] 0.31 | [symbol] 0.30 | [symbol] 0.27 | [symbol] 0.33 | [symbol] 0.30 | [symbol] 0.29 | [symbol] 0.32 | [symbol] 0.29 |
| Strain | 725 | 716 | 713 | 724 | 724 | 718 | 715 | 716 |
| Point (C.) | | | | | | | | |
| Anneal | 777 | 768 | 766 | 777 | 776 | 771 | 766 | 768 |
| Point (C.) | | | | | | | | |
| CTE | 34.7 | 34.3 | 34.7 | 34.4 | 35.1 | 33.8 | 34.4 | 33.6 |
| Density | 2.527 | 2.508 | 2.51 | 2.515 | 2.541 | 2.503 | 2.508 | 2.498 |
| Modulus | 82 | 80.9 | 80.6 | 82.4 | 81.7 | 80.7 | 81.8 | 80.4 |
| (GPa) | | | | | | | | |
| T (200) | 1633 | 1625 | 1623 | 1623 | 1636 | 1639 | 1600 | 1639 |
| T(35000) | 1263 | 1255 | 1252 | 1257 | 1264 | 1263 | 1241 | 1263 |
| Liquidus T | 1181 | 1180 | 1182 | 1182 | 1181 | 1180 | 1181 | 1180 |
| Liq | 2.03E+05 | 1.72E+05 | 1.55E+05 | 1.79E+05 | 2.08E+05 | 2.08E+05 | 1.28E+05 | 2.03E+05 |
| Viscosity | | | | | | | | |
| T200P − | 856 | 857 | 857 | 846 | 860 | 868 | 834 | 871 |
| T(ann) | | | | | | | | |
| Mol % | 73 | 74 | 75 | 76 | 77 | 78 | 79 | 80 |
| SiO2 | 68.03 | 69.43 | 68.02 | 68.65 | 67.8 | 67.85 | 69.15 | 68.79 |
| Al2O3 | 12.82 | 12.5 | 12.66 | 12.62 | 12.85 | 12.72 | 12.49 | 12.71 |
| B2O3 | 4.29 | 4.15 | 4.93 | 4.55 | 4.13 | 4.96 | 4.33 | 4.37 |
| MgO | 4.41 | 4.29 | 4.87 | 4.32 | 5.27 | 4.94 | 4.41 | 4.42 |
| CaO | 6.17 | 5.57 | 5.71 | 5.38 | 6.63 | 5.71 | 5.59 | 5.49 |
| SrO | 4.1 | 3.91 | 3.62 | 4.31 | 3.15 | 3.66 | 3.86 | 3.38 |
| BaO | 0.06 | 0.05 | 0.04 | 0.07 | 0.05 | 0.05 | 0.04 | 0.73 |
| SnO2 | 0.1 | 0.09 | 0.11 | 0.1 | 0.09 | 0.1 | 0.1 | 0.09 |
| Fe2O3 | 0.01 | 0.01 | 0.01 | 0.01 | 0.01 | 0.01 | 0.01 | 0.01 |
| ZrO2 | 0 | 0.01 | 0.02 | 0 | 0 | 0 | 0.02 | 0.01 |
| RO/Al2O3 | 1.15 | 1.11 | 1.12 | 1.12 | 1.18 | 1.13 | 1.11 | 1.1 |
| MgO/RO | [symbol] 0.30 | [symbol] 0.31 | [symbol] 0.34 | [symbol] 0.31 | [symbol] 0.35 | [symbol] 0.34 | [symbol] 0.32 | [symbol] 0.32 |
| Strain | 719 | 724 | 716 | 719 | 721 | 715 | 722 | 721 |
| Point (C.) | | | | | | | | |
| Anneal | 772 | 777 | 766 | 771 | 773 | 765 | 774 | 773 |
| Point (C.) | | | | | | | | |
| CTE | 35.3 | 34 | 34.2 | 34.6 | 34.8 | 34.3 | 34.1 | 34.4 |
| Density | 2.527 | 2.509 | 2.507 | 2.518 | 2.517 | 2.509 | 2.508 | 2.524 |
| Modulus | 82.1 | 81.6 | 81.6 | 81.4 | 83 | 81.7 | 81.5 | 81.5 |
| (GPa) | | | | | | | | |
| T (200) | 1611 | 1640 | 1611 | 1627 | 1598 | 1606 | 1634 | 1631 |
| T(35000) | 1249 | 1266 | 1247 | 1257 | 1242 | 1244 | 1262 | 1260 |
| Liquidus T | 1187 | 1185 | 1180 | 1183 | 1185 | 1180 | 1190 | 1180 |
| Liq | 1.31E+05 | 1.98E+05 | 1.48E+05 | 1.70E+05 | 1.22E+05 | 1.41E+05 | 1.62E+05 | 1.97E+05 |
| Viscosity | | | | | | | | |
| T200P − | 839 | 863 | 845 | 856 | 825 | 841 | 860 | 858 |
| T(ann) | | | | | | | | |
| Mol % | 81 | 82 | M1 | M2 | M3 | M4 | M5 | M6 |
| SiO2 | 69.1 | 68.91 | 66.13 | 68.63 | 66.63 | 69.88 | 69.38 | 67.63 |
| Al2O3 | 12.6 | 12.88 | 13 | 11.25 | 13 | 12.75 | 12.75 | 12.25 |
| B2O3 | 4.07 | 4.35 | 5.25 | 4.5 | 6 | 2.5 | 4 | 5.25 |
| MgO | 4.1 | 4.32 | 5.5 | 5 | 4.75 | 5 | 2.5 | 6.25 |
| CaO | 5.2 | 5.35 | 7 | 6 | 6.25 | 6.5 | 6.5 | 4.75 |
| SrO | 3.78 | 4.09 | 1 | 3.25 | 1.5 | 1.75 | 3.75 | 1 |
| BaO | 1.03 | 0 | 2 | 1.25 | 1.75 | 1.5 | 1 | 2.75 |
| SnO2 | 0.1 | 0.09 | 0.1 | 0.1 | 0.1 | 0.1 | 0.1 | 0.1 |
| Fe2O3 | 0.01 | 0.01 | | | | | | |
| ZrO2 | 0 | 0 | | | | | | |
| RO/Al2O3 | 1.12 | 1.07 | 1.19 | 1.38 | 1.10 | 1.16 | 1.08 | 1.20 |
| MgO/RO | [symbol] 0.29 | [symbol] 0.31 | 0.35 | 0.32 | 0.33 | 0.34 | 0.18 | 0.42 |
| Strain | 723 | 723 | | | | | | |
| Point (C.) | | | | | | | | |
| Anneal | 775 | 775 | 756 | 756 | 755 | 789 | 781 | 756 |
| Point (C.) | | | | | | | | |
| CTE | 35.1 | 33.9 | 35.6 | 36.5 | 34.5 | 34.4 | 35.3 | 34.4 |
| Density | 2.54 | 2.512 | 2.534 | 2.541 | 2.519 | 2.541 | 2.540 | 2.541 |
| Modulus | 81.3 | 81.8 | 81.7 | 80.5 | 80.3 | 83.6 | 80.4 | 80.8 |
| (GPa) | | | | | | | | |
| T (200) | 1643 | 1632 | 1580 | 1631 | 1595 | 1652 | 1654 | 1616 |
| T(35000) | 1266 | 1262 | 1225 | 1248 | 1232 | 1277 | 1274 | 1242 |
| Liquidus T | 1181 | 1190 | 1172 | 1186 | 1174 | 1210 | 1216 | 1179 |
| Liq | 2.17E+05 | 1.62E+05 | 1.14E+05 | 1.29E+05 | 1.26E+05 | 1.46E+05 | 1.17E+05 | 1.36E+05 |
| Viscosity | | | | | | | | |
| T200P − | 868 | 857 | 824 | 875 | 841 | 863 | 873 | 860 |
| T(ann) | | | | | | | | |
| Mol % | M7 | M8 | M9 | M10 | M11 | M12 | M13 | M14 |
| SiO2 | 68.88 | 67.38 | 68.38 | 66.63 | 68.38 | 70.13 | 68.38 | 69.13 |
| Al2O3 | 11.75 | 12.5 | 12.5 | 12.75 | 12 | 12.5 | 12 | 13 |
| B2O3 | 5 | 5.75 | 4.75 | 5.75 | 5.25 | 4.5 | 5.5 | 5 |
| MgO | 6.25 | 4 | 4.5 | 4.25 | 6 | 3.25 | 6.25 | 4 |
| CaO | 2.75 | 8.25 | 3.75 | 6.25 | 4.25 | 6.25 | 4 | 5.5 |
| SrO | 3.5 | 1.5 | 5.75 | 4.25 | 1 | 3.25 | 1.25 | 1.25 |
| BaO | 1.75 | 0.5 | 0.25 | 0 | 3 | 0 | 2.5 | 2 |
| SnO2 | 0.1 | 0.1 | 0.1 | 0.1 | 0.1 | 0.1 | 0.1 | 0.1 |
| Fe2O3 | | | | | | | | |
| ZrO2 | | | | | | | | |
| RO/Al2O3 | 1.21 | 1.14 | 1.14 | 1.16 | 1.19 | 1.02 | 1.17 | 0.98 |
| MgO/RO | 0.44 | 0.28 | 0.32 | 0.29 | 0.42 | 0.25 | 0.45 | 0.31 |
| Strain | | | | | | | | |
| Point (C.) | | | | | | | | |
| Anneal | 760 | 757 | 767 | 756 | 757 | 780 | 756 | 772 |
| Point (C.) | | | | | | | | |
| CTE | 34.1 | 34.5 | 34.9 | 35.5 | 34.0 | 32.8 | 33.4 | 32.9 |
| Density | 2.539 | 2.485 | 2.540 | 2.515 | 2.541 | 2.484 | 2.525 | 2.513 |
| Modulus | 80.3 | 80.3 | 80.3 | 80.3 | 80.2 | 80.3 | 80.3 | 80.2 |
| (GPa) | | | | | | | | |
| T (200) | 1645 | 1598 | 1630 | 1587 | 1635 | 1659 | 1633 | 1650 |
| T(35000) | 1259 | 1233 | 1256 | 1227 | 1252 | 1276 | 1250 | 1270 |
| Liquidus T | 1191 | 1179 | 1199 | 1160 | 1178 | 1215 | 1185 | 1202 |
| Liq | 1.45E+05 | 1.13E+05 | 1.16E+05 | 1.56E+05 | 1.69E+05 | 1.24E+05 | 1.39E+05 | 1.49E+05 |
| Viscosity | | | | | | | | |
| T200P − | 885 | 841 | 863 | 831 | 878 | 879 | 877 | 878 |
| T(ann) | | | | | | | | |
| Mol % | M15 | M16 | M17 | M18 | M19 | M20 | M21 | M22 |
| SiO2 | 68.13 | 69.13 | 68.88 | 68.13 | 69.13 | 68.38 | 68.38 | 68.63 |
| Al2O3 | 12.75 | 12.5 | 12.25 | 13 | 12.75 | 12.75 | 12.75 | 12.5 |
| B2O3 | 4.25 | 3.75 | 4 | 4.5 | 3.5 | 4.75 | 4.25 | 4 |
| MgO | 4.25 | 4 | 4.25 | 4 | 4.25 | 4.5 | 3.75 | 5.25 |
| CaO | 6.75 | 6.5 | 6.75 | 6.25 | 6.75 | 6.25 | 6.75 | 6 |
| SrO | 2.75 | 3.25 | 2.75 | 3 | 2.5 | 3 | 3.25 | 2 |
| BaO | 1 | 0.75 | 1 | 1 | 1 | 0.25 | 0.75 | 1.5 |
| SnO2 | 0.1 | 0.1 | 0.1 | 0.1 | 0.1 | 0.1 | 0.1 | 0.1 |
| Fe2O3 | | | | | | | | |
| ZrO2 | | | | | | | | |
| RO/Al2O3 | 1.16 | 1.16 | 1.20 | 1.10 | 1.14 | 1.10 | 1.14 | 1.18 |
| MgO/RO | 0.29 | 0.28 | 0.29 | 0.28 | 0.29 | 0.32 | 0.26 | 0.36 |
| Strain | | | | | | | | |
| Point (C.) | | | | | | | | |
| Anneal | 770 | 777 | 770 | 772 | 780 | 769 | 773 | 770 |
| Point (C.) | | | | | | | | |
| CTE | 35.3 | 35.1 | 35.3 | 34.8 | 34.7 | 33.8 | 35.3 | 34.6 |
| Density | 2.532 | 2.531 | 2.530 | 2.530 | 2.530 | 2.501 | 2.531 | 2.533 |
| Modulus | 81.6 | 81.7 | 81.4 | 81.2 | 82.3 | 81.2 | 81.3 | 82.0 |
| (GPa) | | | | | | | | |
| T (200) | 1620 | 1639 | 1634 | 1623 | 1638 | 1620 | 1625 | 1629 |
| T(35000) | 1252 | 1264 | 1258 | 1255 | 1266 | 1252 | 1256 | 1257 |
| Liquidus T | 1181 | 1189 | 1187 | 1184 | 1193 | 1180 | 1184 | 1187 |
| Liq | 1.66E+05 | 1.78E+05 | 1.62E+05 | 1.65E+05 | 1.72E+05 | 1.68E+05 | 1.68E+05 | 1.59E+05 |
| Viscosity | | | | | | | | |
| T200P − | 849 | 862 | 863 | 852 | 858 | 851 | 853 | 859 |
| T(ann) | | | | | | | | |
| Mol % | M23 | M24 | M25 | M26 | M27 | M28 | M29 | M30 |
| SiO2 | 68.38 | 68.88 | 68.63 | 68.38 | 68.38 | 68.63 | 68.88 | 68.63 |
| Al2O3 | 12.75 | 12.5 | 12.5 | 12.75 | 12.75 | 12.5 | 12.75 | 12.5 |
| B2O3 | 4.5 | 4.25 | 4.25 | 4.5 | 4.75 | 4.25 | 4.5 | 4.25 |
| MgO | 4.75 | 4 | 4.5 | 4.75 | 4.5 | 4.5 | 4.25 | 5.25 |
| CaO | 4.75 | 7.25 | 6.75 | 4.75 | 6.25 | 6.75 | 6.25 | 4.75 |
| SrO | 4.25 | 1.75 | 1.5 | 4.25 | 3 | 1.5 | 3 | 3.75 |
| BaO | 0.5 | 1.25 | 1.75 | 0.5 | 0.25 | 1.75 | 0.25 | 0.75 |
| SnO2 | 0.1 | 0.1 | 0.1 | 0.1 | 0.1 | 0.1 | 0.1 | 0.1 |
| Fe2O3 | | | | | | | | |
| ZrO2 | | | | | | | | |
| RO/Al2O3 | 1.12 | 1.14 | 1.16 | 1.12 | 1.10 | 1.16 | 1.08 | 1.16 |
| MgO/RO | 0.33 | 0.28 | 0.31 | 0.33 | 0.32 | 0.31 | 0.31 | 0.36 |
| Strain | | | | | | | | |
| Point (C.) | | | | | | | | |
| Anneal | 770 | 771 | 769 | 770 | 769 | 769 | 774 | 770 |
| Point (C.) | | | | | | | | |
| CTE | 34.4 | 34.7 | 34.8 | 34.4 | 33.8 | 34.8 | 33.6 | 34.4 |
| Density | 2.529 | 2.519 | 2.530 | 2.529 | 2.501 | 2.530 | 2.500 | 2.531 |
| Modulus | 81.2 | 81.3 | 81.4 | 81.2 | 81.2 | 81.4 | 81.3 | 81.6 |
| (GPa) | | | | | | | | |
| T (200) | 1626 | 1635 | 1632 | 1626 | 1620 | 1632 | 1631 | 1630 |
| T(35000) | 1256 | 1259 | 1257 | 1256 | 1252 | 1257 | 1259 | 1257 |
| Liquidus T | 1174 | 1189 | 1185 | 1174 | 1180 | 1185 | 1187 | 1183 |
| Liq | 2.15E+05 | 1.61E+05 | 1.68E+05 | 2.15E+05 | 1.68E+05 | 1.68E+05 | 1.68E+05 | 1.78E+05 |
| Viscosity | | | | | | | | |
| T200P − | 856 | 863 | 863 | 856 | 851 | 863 | 857 | 860 |
| T(ann) | | | | | | | | |
| Mol % | M40 | M41 | M42 | M43 | M44 | M45 | M46 | M47 |
| SiO2 | 69.13 | 68.38 | 68.63 | 68.88 | 68.38 | 68.88 | 68.63 | 68.88 |
| Al2O3 | 12.75 | 12.75 | 13 | 12.5 | 12.75 | 12.75 | 12.75 | 12.75 |
| B2O3 | 3.75 | 4.25 | 4 | 4 | 4.25 | 4 | 4.25 | 4 |
| MgO | 4 | 4.25 | 4.25 | 4.25 | 4.75 | 4 | 4.75 | 4 |
| CaO | 6.25 | 6.25 | 6 | 6.5 | 5.75 | 6 | 5.25 | 6.75 |
| SrO | 3.5 | 3.25 | 3.25 | 2.75 | 3.25 | 3.75 | 3.5 | 2.5 |
| BaO | 0.5 | 0.75 | 0.75 | 1 | 0.75 | 0.5 | 0.75 | 1 |
| SnO2 | 0.1 | 0.1 | 0.1 | 0.1 | 0.1 | 0.1 | 0.1 | 0.1 |
| Fe2O3 | | | | | | | | |
| ZrO2 | | | | | | | | |
| RO/Al2O3 | 1.12 | 1.14 | 1.10 | 1.16 | 1.14 | 1.12 | 1.12 | 1.12 |
| MgO/RO | 0.28 | 0.29 | 0.30 | 0.29 | 0.33 | 0.28 | 0.33 | 0.28 |
| Strain | | | | | | | | |
| Point (C.) | | | | | | | | |
| Anneal | 780 | 772 | 777 | 773 | 771 | 777 | 773 | 776 |
| Point (C.) | | | | | | | | |
| CTE | 34.6 | 34.9 | 34.5 | 34.9 | 34.6 | 34.7 | 34.3 | 34.6 |
| Density | 2.526 | 2.529 | 2.529 | 2.529 | 2.527 | 2.528 | 2.528 | 2.525 |
| Modulus | 81.8 | 81.5 | 81.9 | 81.6 | 81.7 | 81.5 | 81.5 | 81.6 |
| (GPa) | | | | | | | | |
| T (200) | 1638 | 1625 | 1630 | 1635 | 1624 | 1635 | 1631 | 1635 |
| T(35000) | 1266 | 1255 | 1261 | 1261 | 1255 | 1263 | 1259 | 1262 |
| Liquidus T | 1188 | 1177 | 1184 | 1184 | 1178 | 1178 | 1182 | 1186 |
| Liq | 1.90E+05 | 1.98E+05 | 1.92E+05 | 1.87E+05 | 1.89E+05 | 2.24E+05 | 1.90E+05 | 1.87E+05 |
| Viscosity | | | | | | | | |
| T200P − | 859 | 853 | 853 | 862 | 853 | 858 | 858 | 859 |
| T(ann) | | | | | | | | |

| Mol % | M48 | M49 | M50 |
|---|---|---|---|
| SiO2 | 68.63 | 68.88 | 68.38 |
| Al2O3 | 12.75 | 12.75 | 12.75 |
| B2O3 | 4.25 | 4 | 4.25 |
| MgO | 4.25 | 4.25 | 4.5 |
| CaO | 6 | 5.75 | 6.25 |
| SrO | 3.75 | 3.75 | 2.75 |
| BaO | 0.25 | 0.5 | 1 |
| SnO2 | 0.1 | 0.1 | 0.1 |
| Fe2O3 | | | |
| ZrO2 | | | |
| RO/Al2O3 | 1.12 | 1.12 | 1.14 |
| MgO/RO | 0.30 | 0.30 | 0.31 |
| Strain | | | |
| Point (C.) | | | |
| Anneal | 774 | 776 | 771 |
| Point (C.) | | | |
| CTE | 34.4 | 34.5 | 34.8 |
| Density | 2.518 | 2.527 | 2.528 |
| Modulus | 81.5 | 81.6 | 81.6 |
| (GPa) | | | |
| T (200) | 1627 | 1634 | 1625 |
| T(35000) | 1257 | 1262 | 1255 |
| Liquidus T | 1178 | 1178 | 1179 |
| Liq | 2.00E+05 | 2.25E+05 | 1.86E+05 |
| Viscosity | | | |
| T200P − | 853 | 858 | 854 |
| T(ann) | | | |

| Mol % | M51 | M52 | M53 | M54 | M55 | M56 |
|---|---|---|---|---|---|---|
| SiO2 | 69.32 | 69.15 | 67.79 | 68.45 | 68.53 | 67.71 |
| Al2O3 | 12.50 | 12.49 | 12.89 | 12.60 | 12.54 | 12.90 |
| B2O3 | 4.25 | 4.33 | 4.93 | 4.31 | 4.34 | 4.93 |
| MgO | 4.29 | 4.41 | 4.60 | 4.81 | 4.72 | 4.61 |
| CaO | 5.57 | 5.59 | 5.99 | 5.34 | 5.46 | 5.72 |
| SrO | 3.91 | 3.86 | 3.64 | 4.31 | 3.79 | 3.96 |
| BaO | 0.05 | 0.04 | 0.05 | 0.07 | 0.51 | 0.06 |
| SnO2 | 0.09 | 0.10 | 0.10 | 0.10 | 0.10 | 0.10 |
| Fe2O3 | 0.01 | 0.01 | 0.01 | 0.01 | 0.01 | 0.01 |
| ZrO2 | 0.01 | 0.02 | 0.00 | 0.00 | 0.00 | 0.00 |
| Density | 2.507 | 2.506 | 2.509 | 2.521 | 2.525 | 2.515 |
| Anneal | 775 | 774 | 767 | 771 | 770 | 767 |
| Point (C.) | | | | | | |
| Modulus | 81.2 | 81.3 | 81.2 | 81.5 | 81.3 | 81.1 |
| (GPa) | | | | | | |
| T(35000) | 1265 | 1261 | 1245 | 1254 | 1256 | 1245 |
| T(200) | 1640 | 1636 | 1609 | 1622 | 1627 | 1608 |
| Mol % | M57 | M58 | M59 | M60 | M61 | M62 |
| SiO2 | 68.98 | 68.74 | 68.56 | 68.79 | 68.63 | 68.92 |
| Al2O3 | 12.67 | 12.71 | 12.53 | 12.92 | 12.84 | 12.69 |
| B2O3 | 4.92 | 4.40 | 4.91 | 4.24 | 3.93 | 4.22 |
| MgO | 3.79 | 4.17 | 4.21 | 4.34 | 4.39 | 4.11 |
| CaO | 5.32 | 5.41 | 5.57 | 5.43 | 6.14 | 5.95 |
| SrO | 4.22 | 3.49 | 4.05 | 4.18 | 3.90 | 4.00 |
| BaO | 0.00 | 0.97 | 0.04 | 0.00 | 0.06 | 0.00 |
| SnO2 | 0.09 | 0.08 | 0.09 | 0.09 | 0.10 | 0.10 |
| Fe2O3 | 0.01 | 0.01 | 0.01 | 0.01 | 0.01 | 0.01 |
| ZrO2 | 0.00 | 0.02 | 0.03 | 0.00 | 0.00 | 0.00 |
| Density | 2.502 | 2.534 | 2.506 | 2.514 | 2.520 | 2.511 |
| Anneal | 772 | 772 | 768 | 777 | 777 | 776 |
| Point (C.) | | | | | | |
| Modulus | 80.1 | 80.9 | 80.8 | 81.5 | 82.0 | 81.3 |
| (GPa) | | | | | | |
| T(35000) | 1262 | 1262 | 1253 | 1261 | 1257 | 1261 |
| T(200) | 1638 | 1637 | 1626 | 1630 | 1624 | 1632 |
| Mol % | M63 | M64 | M65 | M66 | M67 | M68 |
| SiO2 | 68.36 | 69.52 | 68.49 | 68.73 | 69.07 | 69.14 |
| Al2O3 | 12.53 | 12.34 | 12.60 | 12.70 | 12.61 | 12.58 |
| B2O3 | 5.03 | 4.16 | 4.40 | 4.41 | 4.23 | 4.08 |
| MgO | 4.19 | 4.58 | 4.61 | 4.19 | 4.41 | 4.39 |
| CaO | 5.58 | 5.24 | 5.56 | 5.42 | 5.63 | 5.57 |
| SrO | 4.13 | 4.07 | 3.48 | 3.49 | 3.95 | 4.05 |
| BaO | 0.05 | 0.00 | 0.75 | 0.95 | 0.00 | 0.07 |
| SnO2 | 0.09 | 0.08 | 0.10 | 0.08 | 0.09 | 0.11 |
| Fe2O3 | 0.01 | 0.01 | 0.01 | 0.01 | 0.01 | 0.01 |
| ZrO2 | 0.03 | 0.00 | 0.00 | 0.02 | 0.00 | 0.00 |
| Density | 2.508 | 2.505 | 2.527 | 2.533 | 2.508 | 2.513 |
| Anneal | 766 | 774 | 770 | 772 | 775 | 776 |
| Point (C.) | | | | | | |
| Modulus | 80.6 | 81.1 | 81.2 | 80.9 | 81.3 | 81.3 |
| (GPa) | | | | | | |
| T(35000) | 1251 | 1266 | 1257 | 1262 | 1262 | 1263 |
| T(200) | 1622 | 1644 | 1628 | 1636 | 1635 | 1637 |

| Mol % | M69 |
|---|---|
| SiO2 | 68.80 |
| Al2O3 | 12.83 |
| B2O3 | 4.06 |
| MgO | 4.72 |
| CaO | 5.54 |
| SrO | 3.88 |
| BaO | 0.06 |
| SnO2 | 0.10 |
| Fe2O3 | 0.01 |
| ZrO2 | 0.00 |
| Density | 2.514 |
| Anneal | 776 |
| Point (C.) | |
| Modulus | 81.9 |
| (GPa) | |
| T(35000) | 1260 |
| T(200) | 1628 |

What is claimed is:

1. A glass comprising, in mole percent on an oxide basis based on 100 mol % of the glass:
$${SiO}_{2} : 68.3 - 70.5 ,$$
$${Al}_{2} {O}_{3} : 11.2 - 13.3 ,$$
$${B}_{2} {O}_{3} : 2.5 - 4.9 ,$$
$$MgO : 2.5 - 6.3 ,$$
$$CaO : 2.7 - 6.5 ,$$
$$SrO : 1 - 5.8 , and$$
$$BaO : 0 - 3 ,$$
wherein a sum of concentrations of Li₂O, Na₂O, and K₂O less than 0.1 mol % in the glass, and SiO₂+Al₂O₃ is greater than or equal to 82.0 mol %.

2. The glass of claim 1, comprising, in mole percent on the oxide basis:
$${SiO}_{2} : 68.7 - 69.5 ,$$
$${Al}_{2} {O}_{3} : 12.4 - 13 ,$$
$${B}_{2} {O}_{3} : 3.7 - 4.5 ,$$
$$MgO : 4. - 4.9 ,$$
$$CaO : 5.2 - 6.8 ,$$
$$SrO : 2.5 - 4.2 , and$$
$$BaO : 0 - 3 ,$$
wherein the glass has an annealing point greater than or equal to 770° C. and less than 810° C.

3. The glass of claim 1, comprising, in mole percent on the oxide basis:
$${SiO}_{2} : 68.7 - 70.5 ,$$
$${Al}_{2} {O}_{3} : 12.2 - 13 ,$$
$${B}_{2} {O}_{3} : 3.5 - 4.8 ,$$
$$MgO : 3.7 - 5.3 ,$$
$$CaO : 4.7 - 6.25 ,$$
$$SrO : 1.5 - 4.4 , and$$
$$BaO : 1.25 - 2.$$

4. The glass of claim 1, wherein 1.07≤(MgO+CaO+SrO+BaO)/Al₂O₃≤1.2.

5. The glass of claim 1, wherein 0.24≤MgO/(MgO+CaO+SrO+BaO)≤0.36.

6. The glass of claim 1, wherein the glass exhibits:
an annealing point temperature greater than or equal to 770° C.; and
a difference between a temperature corresponding a viscosity of the glass of 200 Poise and an annealing point temperature (T200P−T(ann)) is less than 890° C.

7. The glass of claim 1, wherein the glass exhibits:
an annealing point temperature greater than 765° C.; and
a liquidus viscosity of greater than 150,000 Poise.

8. The glass of claim 1, wherein the glass exhibits:
a liquidus viscosity greater than 100,000 Poise;
a Young's Modulus of greater than 80 GPa; and
a density less than 2.55 g/cc.

9. The glass of claim 1, wherein the glass has a temperature corresponding to a viscosity of the glass of 200 Poise (T200P) of less than 1665° C.

10. The glass of claim 1, wherein the glass has a temperature corresponding to a viscosity of the glass of 35 kiloPoise (T35kP) of less than 1280° C.

11. The glass of claim 1, wherein the glass has an annealing point in the range defined by the relationship:
$$720 °C . \leq 1464.862 - 6.339 * {SiO}_{2} - 1.286 * {Al}_{2} {O}_{3} - 17.284 * {B}_{2} {O}_{3} - 12.216 * MgO - 11.448 * CaO - 11.367 * SrO - 12.832 * BaO \leq 810 °C . ,$$
where SiO₂, Al₂O₃, B₂O₃, MgO, CaO, SrO, and BaO represent the mole percents of the oxide components of the glass.

12. The glass of claim 1, wherein the glass comprises As₂O₃ and Sb₂O₃ in an amount of less than 0.005 mol %.

13. A liquid crystal display substrate comprising the glass of claim 1.

14. A glass comprising, in mole percent on an oxide basis based on 100 mol % of the glass:
$${SiO}_{2} : 68.3 - 70.5 ,$$
$${Al}_{2} {O}_{3} : 11.2 - 13.3 ,$$
$${B}_{2} {O}_{3} : 2.5 - 4.9 ,$$
$$MgO : 2.5 - 6.3 ,$$
$$CaO : 2.7 - 6.5 ,$$
$$SrO : 1 - 5.8 , and$$
$$BaO : 0 - 3 ,$$
wherein a sum of concentrations of Li₂O, Na₂O, and K₂O less than 0.1 mol % in the glass, and the glass exhibits:
an annealing point temperature greater than or equal to 770° C.;
a difference between a temperature corresponding a viscosity of the glass of 200 Poise and an annealing point temperature (T200P−T(ann)) is less than 890° C.; and
a liquidus viscosity greater than 100,000 Poise.

15. The glass of claim 14, wherein:
$$1.07 \leq ( MgO + CaO + SrO + BaO ) / {Al}_{2} {O}_{3} \leq 1.2 ; and$$
$$0.24 \leq MgO / ( MgO + CaO + SrO + BaO ) \leq 0.36 .$$

16. The glass of claim 14, wherein the glass exhibits:
a liquidus viscosity greater than 100,000 Poise;
a Young's Modulus of greater than 80 GPa; and
a density less than 2.55 g/cc.

17. The glass of claim 1, wherein the glass exhibits a temperature corresponding to a viscosity of the glass of 35 kiloPoise (T35kP) of less than 1280° C., wherein the temperature corresponding to a viscosity of the glass of 200 Poise (T200P) is less than 1665° C.

18. The glass of claim 14, comprising, in mole percent on the oxide basis:
$${SiO}_{2} : 68.7 - 69.5 ,$$
$${Al}_{2} {O}_{3} : 12.4 - 13 ,$$
$${B}_{2} {O}_{3} : 3.7 - 4.5 ,$$
$$MgO : 4. - 4.9 ,$$
$$CaO : 5.2 - 6.8 ,$$
$$SrO : 2.5 - 4.2 , and$$
$$BaO : 0 - 3.$$

19. The glass of claim 14, comprising, in mole percent on the oxide basis:
$${SiO}_{2} : 68.7 - 70.5 ,$$
$${Al}_{2} {O}_{3} : 12.2 - 13 ,$$
$${B}_{2} {O}_{3} : 3.5 - 4.8 ,$$
$$MgO : 3.7 - 5.3 ,$$
$$CaO : 4.7 - 6.25 ,$$
$$SrO : 1.5 - 4.4 , and$$
$$BaO : 1.25 - 2.$$

20. A glass comprising, in mole percent on an oxide basis:
$${SiO}_{2} : 68.3 - 69.5 ,$$
$${Al}_{2} {O}_{3} : 12.4 - 13 ,$$
$${B}_{2} {O}_{3} : 3.7 - 4.5 ,$$
$$MgO : 4 - 4.9 ,$$
$$CaO 5.2 - 6.8 ,$$
$$SrO 2.5 - 4.2 ,$$
$$BaO 0 - 1 ,$$
wherein: 1.09≤(MgO+CaO+SrO+BaO)/Al₂O₃≤1.13,
wherein the glass has a Young's modulus in the range defined by the relationship:
$$70 G Pa \leq 549.899 - 4.811 * {SiO}_{2} - 4.023 * {Al}_{2} {O}_{3} - 5.651 * {B}_{2} {O}_{3} - 4.004 * MgO - 4.453 * CaO - 4.753 * SrO - 5.041 * BaO \leq 90 G Pa ,$$
and
wherein the glass has an annealing point in the range defined by the relationship:
$$720 °C . \leq 1464.862 - 6.339 * {SiO}_{2} - 1.286 * {Al}_{2} {O}_{3} - 17.284 * {B}_{2} {O}_{3} - 12.216 * MgO - 11.448 * CaO - 11.367 * SrO - 12.832 * BaO \leq 810 °C . ,$$
where SiO₂, Al₂O₃, B₂O₃, MgO, CaO, SrO, and BaO represent the mole percents of the oxide components of said glass.
